(19) United States
(12) Patent Application Publication
(10) Pub. No.: US 2024/0142539 A1
(43) Pub. Date: May 2, 2024

(54) BATTERY MONITORING DEVICE, WIRELESS TRANSMISSION METHOD OF BATTERY-RELATED INFORMATION, AND NON-TRANSITORY COMPUTER READABLE MEDIUM

(71) Applicant: DENSO CORPORATION, Kariya-city (JP)

(72) Inventors: Shogo SHIGEMORI, Kariya-city (JP); Tatsuhiro NUMATA, Kariya-city (JP); Tetsuya WATANABE, Kariya-city (JP)

(21) Appl. No.: 18/472,456

(22) Filed: Sep. 22, 2023

(30) Foreign Application Priority Data
Oct. 31, 2022 (JP) 2022-174500

(51) Int. Cl. G01R 31/396; B60L 58/12; B60L 58/16; B60L 58/18; G01R 31/00; H01M 10/42

(52) U.S. Cl. CPC G01R 31/396; B60L 58/12; B60L 58/16; B60L 58/18; G01R 31/006; H01M 10/4257; H01M 2010/4278

(57) ABSTRACT

A battery monitoring includes a plurality of monitoring units and a wireless transmission unit. The plurality of monitoring units is configured to acquire battery-related information including at least information indicating a state of a battery. The wireless transmission unit is configured to wirelessly transmit the battery-related information acquired by the plurality of monitoring units to a control device.

### CROSS REFERENCE TO RELATED APPLICATION

The present application claims the benefit of priority from Japanese Patent Application No. 2022-174500 filed on Oct. 31, 2022. The entire disclosure of the above application is incorporated herein by reference.

### TECHNICAL FIELD

The present disclosure relates to a battery monitoring device, a wireless transmission method of battery-related information, and a non-transitory computer readable medium.

### BACKGROUND

For example, a vehicle such as a hybrid vehicle (HV), a plug-in hybrid vehicle (PHV), or an electric vehicle (EV) has an assembled battery such as a lithium ion battery for running the vehicle, and a battery monitoring device is adopted to monitor an operation state of the assembled battery.

### SUMMARY

A battery monitoring device according to an aspect of the present disclosure includes a plurality of monitoring units and a wireless transmission unit. The plurality of monitoring units is configured to acquire battery-related information including at least information indicating a state of a battery. The wireless transmission unit is configured to wirelessly transmit the battery-related information acquired by the plurality of monitoring units to a control device.

A wireless transmission method according to another aspect of the present disclosure includes: acquiring battery-related information including at least information indicating a state of a battery by a plurality of monitoring units; transmitting the battery-related information from the plurality of monitoring units to a wireless transmission unit that is connected to the plurality of monitoring units in a wired manner; and wirelessly transmitting the battery-related information from the wireless transmission unit to a control device.

A non-transitory computer readable medium according to another aspect of the present disclosure stores a program including instructions for a battery monitoring device. The battery monitoring device includes a plurality of monitoring units configured to acquire battery-related information including at least information indicating a state of a battery and a wireless transmission unit communicably connected to the plurality of monitoring units and configured to wirelessly transmit the battery-related information. The instructions are configured to: cause the plurality of monitoring units to acquire the battery-related information; cause the plurality of monitoring units to transmit the battery-related information to the wireless transmission unit; and cause the wireless transmission unit to wirelessly transmit the battery-related information to a control device.

### BRIEF DESCRIPTION OF DRAWINGS

Objects, features and advantages of the present disclosure will become apparent from the following detailed description made with reference to the accompanying drawings. In the drawings:

FIG. 1 is a block diagram schematically illustrating a battery monitoring system according to a first embodiment;

FIG. 2 is a diagram schematically illustrating a structure of a battery pack;

FIG. 3 is a side view of a battery module and a monitoring device;

FIG. 4 is a plan view schematically illustrating a structure of the battery pack and a wireless propagation path;

FIG. 5 is an electrical configuration diagram of the battery monitoring system;

FIG. 6 is a first communication sequence diagram schematically illustrating a flow of a communication establishment process between the monitoring device and a control device;

FIG. 7 is a second communication sequence diagram schematically illustrating a flow of a communication establishment process between the monitoring device and the control device;

FIG. 8 is a sequence diagram schematically illustrating a flow of a communication process between the monitoring device and the control device;

FIG. 9 is an explanatory diagram illustrating relationships between types of data and data amounts and combination examples of transmission data types;

FIG. 10 is an explanatory diagram illustrating the combination examples of the transmission data types;

FIG. 11 is a first diagram schematically illustrating a transmission order of data;

FIG. 12 is a sequence diagram of a communication process;

FIG. 13 is a second diagram schematically illustrating a transmission order of data;

FIG. 14 is a perspective view schematically illustrating a structure of a battery pack according to a second embodiment;

FIG. 15 is a perspective view schematically illustrating a structure of a battery pack according to a third embodiment;

FIG. 16 is a perspective view schematically illustrating a structure of a battery pack according to a fourth embodiment; and

FIG. 17 is an electrical configuration diagram of a battery monitoring system according to a fifth embodiment.

### DETAILED DESCRIPTION

Next, a relevant technology is described only for understanding the following embodiments. A battery system monitor according to the relevant technology includes a cell measurement circuit that measures a voltage of a pair of terminals of a battery module or a current passing through the pair of terminals from among a plurality of battery modules in a battery system.

Wireless communication transceivers are each associated with a different cell measurement circuit and transmit information of the voltage or the current measured by the cell measurement circuit. A control device is configured to receive the information of the voltage or the current from the wireless communication transceiver to monitor the operating state of the battery system.

When a plurality of monitoring units is communicably connected to a wireless transmission unit, battery-related information acquired for each of the monitoring units is wirelessly transmitted. However, when the wireless transmission unit wirelessly transmits the battery-related information acquired for each of the monitoring units, the number of times of wireless transmission increases. Then, for example, the number of times of monitoring a battery per unit time decreases, which leads to a delay in finding an abnormality related to the battery.

A battery monitoring device according to an aspect of the present disclosure includes a plurality of monitoring units and a wireless transmission unit. The plurality of monitoring units is configured to acquire battery-related information including at least information indicating a state of a battery. The wireless transmission unit is configured to wirelessly transmit the battery-related information acquired by the plurality of monitoring units to a control device. As compared with a configuration in which one monitoring unit is provided for the wireless transmission unit, the amount of data transmitted by the wireless transmission unit can be increased, and the number of times of wireless transmission of the battery-related information can be restricted.

When wireless communication is applied, an error is more likely to occur than in wired communication because there is a restriction on a wireless communication state. However, even when the amount of data is increased, it is desirable to restrict an error rate as much as possible and restrict the number of retransmissions and the number of wireless transmissions as much as possible.

The wireless transmission unit may wirelessly transmit different types of information among the battery-related information acquired by the plurality of monitoring units. In this case, the wireless transmission unit may wirelessly transmit the different types of information collectively, so that the total amount of data to be transmitted collectively can be restricted. As a result, communication errors in wireless communication can be restricted. Accordingly, it is possible to restrict a decrease in the number of times of monitoring the battery per unit time. Therefore, safety can be improved without missing detection of an abnormality related to the battery as much as possible.

Among the battery-related information acquired by the plurality of monitoring units, a plurality of pieces of information may be collectively transmitted in a combination of types of information having a smaller data amount than a combination of types of information having the largest data amount. In this case, since wireless transmission is performed in a combination in which the amount of data is reduced, the amount of data to be transmitted collectively can be restricted, and the error rate of wireless communication can be restricted. The wireless transmission unit may wirelessly transmit the battery-related information acquired by the plurality of monitoring units in such a manner that the total amount of data to be wirelessly transmitted collectively falls within a predetermined range by combining types of data of the battery-related information. In this case, for example, the total amount of data to be transmitted collectively can be reduced as compared with a case of wirelessly transmitting a combination of the data types of battery-related information having the largest amount of data. As a result, communication errors in wireless communication can be restricted, and a decrease in the number of times of monitoring the battery can be restricted.

The wireless transmission unit and the plurality of monitoring units may be communicatively connected by a network topology of a star connection. In this case, even when a failure occurs in some of the plurality of monitoring units, the communication connection can be maintained separately with the other monitoring units, and thus the communication connection can be normally continued between the other monitoring units and the wireless transmission unit.

A wireless transmission method according to another aspect of the present disclosure includes: acquiring battery-related information including at least information indicating a state of a battery by a plurality of monitoring units; transmitting the battery-related information from the plurality of monitoring units to a wireless transmission unit that is connected to the plurality of monitoring units in a wired manner; and wirelessly transmitting the battery-related information from the wireless transmission unit to a control device.

A non-transitory computer readable medium according to another aspect of the present disclosure stores a program including instructions for a battery monitoring device. The battery monitoring device includes a plurality of monitoring units configured to acquire battery-related information including at least information indicating a state of a battery and a wireless transmission unit communicably connected to the plurality of monitoring units and configured to wirelessly transmit the battery-related information. The instructions are configured to: cause the plurality of monitoring units to acquire the battery-related information; cause the plurality of monitoring units to transmit the battery-related information to the wireless transmission unit; and cause the wireless transmission unit to wirelessly transmit the battery-related information to a control device.

Hereinafter, some embodiments of a battery monitoring system 1 will be described with reference to the drawings. In the embodiments described below, the same or similar components among the embodiments are assigned the same or similar reference numerals, and description thereof may be omitted.

### First Embodiment

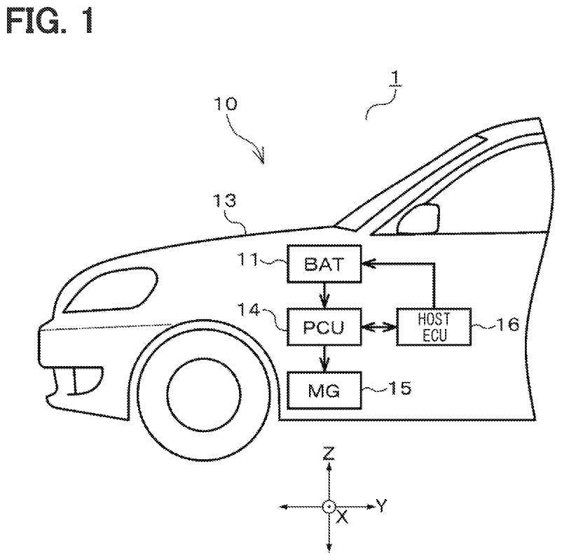

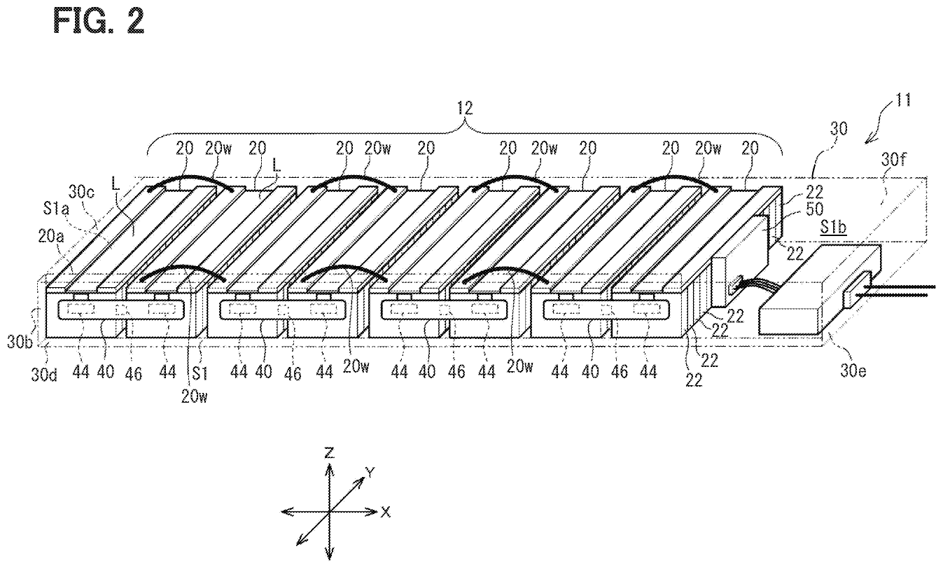

A first embodiment will be described with reference to FIGS. 1 to 13. As shown in FIG. 1, the battery monitoring system 1 is built in a vehicle 10. The vehicle 10 is, for example, a hybrid vehicle (HV), a plug-in hybrid vehicle (PHV), or an electric vehicle (EV). The vehicle 10 uses an assembled battery 12 (see FIG. 2) of a battery pack 11 mounted on the vehicle 10 as at least a part of a drive source for traveling.

The battery pack (BAT) 11, a power control unit (PCU) 14, a motor (MG) 15, and a host ECU 16 are mounted inside a vehicle body 13. The battery pack 11 is installed below an occupant seat (for example, a driver's seat) of the vehicle body 13. The battery pack 11 may be disposed in an engine room of the vehicle body 13, or may be disposed around a frame of the vehicle body 13, in a trunk room, or the like.

As illustrated in FIG. 2, the battery pack 11 includes a plurality of battery modules 20. In each of the plurality of battery modules 20, a plurality of battery cells 22 is grouped. The battery pack 11 includes a plurality of groups of battery modules 20. A large number of battery cells 22 are accommodated in the battery module 20 to form an assembled battery 12. Electric power for driving the motor 15 is stored in the assembled battery 12. The electric power stored in the assembled battery 12 is used as a driving source of the vehicle 10. The PCU 14 illustrated in FIG. 1 supplies the electric power stored in the assembled battery 12 of the battery pack 11 to the motor 15. When the vehicle 10 is braked, the motor 15 returns regenerative electric power to the assembled battery 12, and the assembled battery 12 of the battery pack 11 is charged in accordance with the electric power generated by the motor 15.

### <Structure of Battery Pack 11>

Hereinafter, a structure example of the battery pack 11 will be described with reference to FIGS. 2 to 4. In FIG. 2, an inner wall of a housing 30 is indicated by a long dashed double-dotted line. In the housing 30, a longitudinal direction of the housing 30 is referred to as an X direction, and a lateral direction is referred to as a Y direction. A vertical direction perpendicular to a mounting surface of the housing 30 on the vehicle body 13 is referred to as a Z direction. The X direction, the Y direction, and the Z direction intersect (for example, orthogonal) each other. The X direction corresponds to a predetermined direction, and the Y direction corresponds to an intersecting direction. The housing 30 includes a first wall surface 30a extending along the X direction and a second wall surface 30b extending along the Y direction. The housing 30 is formed in a rectangular box shape of a flat type, a planar type, or a low height type.

As illustrated in FIG. 2, the assembled battery 12, a plurality of monitoring devices 40, and a control device 50 are accommodated in the housing 30 of the battery pack 11 over a plane direction defined by the X direction and the Y direction. The monitoring device 40 corresponds to a battery monitoring device or a main body of the battery monitoring device. Each of the monitoring devices 40 includes a monitoring circuit that monitors the battery pack 11, and is referred to as a satellite battery module (SBM).

A lower surface of the housing 30 in the Z direction is the mounting surface on the vehicle body 13. In the present embodiment, the X direction is the right-left direction of the vehicle 10, the Y direction is the front-rear direction of the vehicle 10, and the Z direction is the up-down direction of the vehicle 10. The arrangement illustrated in FIGS. 2 to 4 is only an example. The mounting direction of the battery pack 11 to the vehicle body 13 is an example, and the battery pack 11 may be disposed in any manner with respect to the vehicle 10.

The assembled battery 12 includes the plurality of battery modules 20 arranged in parallel in the X direction. The battery modules 20 may be referred to as battery stacks, battery blocks, or the like. The assembled battery 12 may be configured by connecting the battery modules 20 in series and/or in parallel, but in the present embodiment, an example in which the battery modules 20 are connected in series is illustrated.

Each of the battery modules 20 includes the battery cells 22 each configured in a rectangular box shape. Each of the battery modules 20 has a configuration in which the battery cells 22 are grouped into a certain group. In each of the battery modules 20, the battery cells 22 are arranged in parallel in the Y direction. Each of the battery cells 22 is accommodated in a battery case (not shown), whereby the relative positions of the battery cells 22 are fixed. The battery case is made of metal or resin. When the battery case is made of metal and formed in a rectangular box shape, an electrically insulating member is entirely interposed between the wall surface of the battery case and the battery cell 22. The insulating member may be partially interposed between the wall surface of the battery case and the battery cell 22.

The mode of the fixing member is not particularly limited as long as the relative positions of the battery cells 22 can be fixed. For example, a configuration in which the battery cells 22 are restrained by a band having a strip shape can be adopted. In this case, a separator for keeping a separation distance between the battery cells 22 may be interposed between the battery cells 22.

Each of the battery modules 20 includes the battery cells 22 connected in series. Each of the battery modules 20 of the present embodiment is configured by the battery cells 22 arranged in the Y direction and connected in series, and the assembled battery 12 provides a direct current (DC) voltage source.

Each of the battery cells 22 is a secondary battery that generates an electromotive force by a chemical reaction. For example, a lithium ion secondary battery, a nickel hydrogen secondary battery, or an organic radical battery can be adopted as the secondary battery. The lithium ion secondary battery is a secondary battery using lithium as a charge carrier. The secondary battery that can be adopted as the battery cell 22 may be not only a secondary battery in which the electrolyte is a liquid but also a so-called all-solid-state battery using a solid electrolyte.

As shown in FIGS. 2 to 4, the battery cells 22 are stacked so that the side surfaces of the battery cases are in contact with each other in the Y direction. Each of the battery cells 22 has a positive electrode terminal 23 and a negative electrode terminal 24 located at both ends in the X direction and protrude in the Z direction, more specifically, in a Z+ direction indicating an upper side. The positions of the protruding end surfaces of the positive electrode terminal 23 and the negative electrode terminal 24 in the Z direction are located at the same height among the battery cells 22. The battery cells 22 are stacked such that the positive electrode terminals 23 and the negative electrode terminals 24 are alternately arranged in the Y direction.

On the upper surface of each of the battery modules 20, a pair of linear bus bar units 25 is disposed at both ends in the X direction. The bus bar units 25 are disposed at both ends in the X direction of the end surfaces of the battery case from which the positive electrode terminal 23 and the negative electrode terminal 24 protrude.

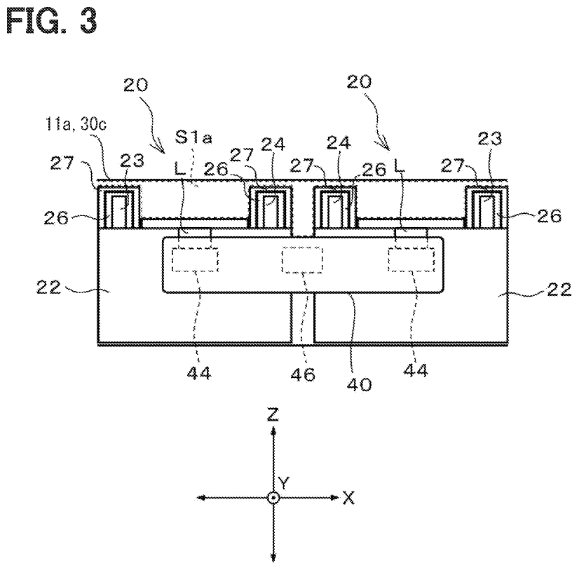

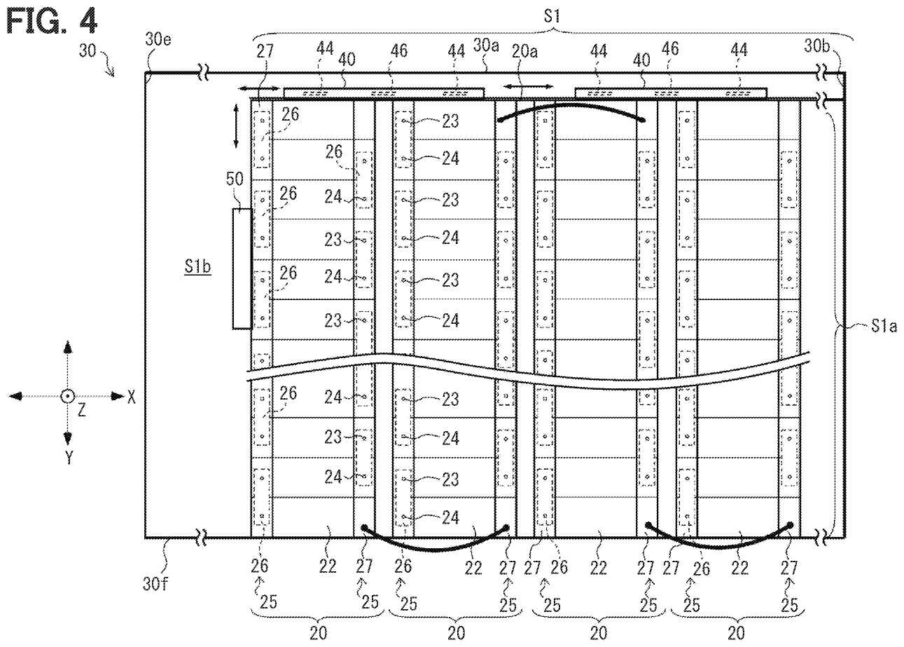

Each of the bus bar units 25 includes a plurality of bus bars 26 electrically connecting the positive electrode terminals 23 and the negative electrode terminals 24 alternately arranged in the Y direction, and a bus bar cover 27 covering the bus bars 26. Each of the bus bars 26 is a plate material made of a metal having superior conductivity such as copper or aluminum. Each of the bus bar 26 electrically connects the positive electrode terminal 23 and the negative electrode terminal 24 of the battery cells 22 adjacent to each other in the Y direction. Accordingly, in each of the battery modules 20, the battery cells 22 are connected in series. Each of the battery modules 20 is configured by arranging the battery cells 22 in parallel in the Y direction. As illustrated in FIG. 3 and FIG. 4, the bus bar covers 27 are disposed along the Y direction so as to cover the positive electrode terminals 23 and the negative electrode terminals 24 of the battery cells 22 in the battery modules 20. As illustrated in FIG. 3, the bus bar covers 27 are disposed at both ends of the battery cells 22 in the X direction and protrude upward from the upper surfaces of the battery cells 22. As illustrated in FIG. 3, a space S1a is provided so as to be surrounded by a top surface 11g of the battery pack, that is, an upper inner surface 30c of the housing 30, an inner surface of the bus bar cover 27, and an upper surface of the battery cell 22. The space S1a is located below the upper inner surface 30c of the housing 30 and is provided so as to communicate in the X direction. As will be described later, the space S1a is provided as a propagation path of an electromagnetic wave.

Here, an electrical connection state of a certain battery module 20 will be described. In the certain battery module 20, one end of a certain first battery cell 22 in the X direction is a positive electrode, and the other end is a negative electrode. A positive electrode terminal 23 is connected to the positive electrode of the battery cell 22, and a negative electrode terminal 24 is connected to the negative electrode of the battery cell 22. A second battery cell 22 is disposed to face a lateral side of the first battery cell 22 in the Y direction. The second battery cell 22 is opposite to the first battery cell 22 in positions of the positive electrode and the negative electrode in the X direction. The negative electrode terminal 24 of the first battery cell 22 is connected to the positive electrode terminal 23 of the second battery cell 22 by the bus bar 26.

Further, a third battery cell 22 is disposed to face a lateral side of the second battery cell 22 in the Y direction. In the third battery cell 22, the positive electrode and the negative electrode are arranged opposite in the X direction with respect to the second battery cell 22, and the negative electrode terminal 24 of the second battery cell 22 and the positive electrode terminal 23 of the third battery cell 22 are connected by the bus bar 26. As described above, the battery cells 22 are arranged in the Y direction while switching the positions of the positive electrode and the negative electrode in the X direction, and the positive electrode terminal 23 and the negative electrode terminal 24 are connected by the bus bar 26. Thus, the battery cells 22 of the battery modules 20 are electrically connected in series.

In each of the battery modules 20, one of two battery cells 22 located at the opposite ends of the battery cells 22 arranged in the Y direction has the highest potential, and the other has the lowest potential. A wire 20w is connected to at least one of the positive electrode terminal 23 of the battery cell 22 having the highest potential and the negative electrode terminal 24 of the battery cell 22 having the lowest potential.

As shown in FIGS. 2 to 4, the positive electrode terminal 23 of the battery cell 22 having the highest potential in one of two battery modules 20 adjacent to each other in the X direction and the negative electrode terminal 24 of the battery cell 22 having the lowest potential in the other are connected to each other via the wire 20w. Thus, the battery modules 20 are electrically connected in series.

One of the two battery modules 20 located at the end portions of the battery modules 20 arranged in the X direction is on the highest potential side, and the other is on the lowest potential side. In the battery module 20 on the highest potential side, an output terminal is connected to the positive electrode terminal 23 of the battery cell 22 having the highest potential among the battery cells 22.

In the battery module 20 on the lowest potential side, an output terminal is connected to the negative electrode terminal 24 of the battery cell 22 having the lowest potential among the battery cells 22. These two output terminals are connected to an electric device such as the PCU 14 mounted on the vehicle 10. The positive electrode terminal 23 and the negative electrode terminal 24 may at least partially face each other or not face each other at all in the X direction.

Note that the two battery modules 20 adjacent to each other in the X direction may not be electrically connected via the wire 20w, and any two of the battery modules 20 may be electrically connected via the wire 20w.

Each of the bus bar covers 27 illustrated in FIG. 3 and FIG. 4 is formed of an electrically insulating material such as resin. Each of the bus bar covers 27 is linearly provided from one end to the other end of the battery module 20 along the Y direction so as to cover the bus bars 26. Each of the bus bar covers 27 may have a partition wall. By providing the partition wall, it is possible to enhance insulation between the two bus bars 26 adjacent to each other in the Y direction.

As shown in FIG. 2, one monitoring device 40 is provided for two battery modules 20 adjacent to each other in the X direction. Here, a configuration in which the monitoring device 40 is provided for each of a pair of adjacent battery modules 20 is shown, but the monitoring device 40 may be provided for each one battery module 20 as shown in a third embodiment described later, or may be provided for each of three or more battery modules 20.

The monitoring device 40 is provided on the inner side of the first wall surface 30a of the housing 30 along the extending direction (X direction) of the first wall surface 30a, and is disposed across the two battery modules 20 along the X direction. The monitoring devices 40 are located at ends of the battery modules 20 in the Y direction and are arranged in the X direction. The monitoring devices 40 are provided on the inner side of the first wall surface 30a extending along the X direction of the housing 30. The monitoring devices 40 are located at the same position in the Y direction.

In the structure illustrated in FIG. 2, the monitoring devices 40 are arranged at ends of the battery modules 20 on one side in the Y direction, but the present disclosure is not limited to this structure. For example, the monitoring devices 40 may be alternately arranged at one end and the other end in the Y direction for each of the two battery modules 20, or may not be regularly arranged alternately.

The monitoring device 40 is fitted into a recess provided in the battery module 20, for example, and is fixed by a screw. A method of fixing the monitoring device 40 is not limited to this method. For example, the monitoring device 40 may be fixed to the battery module 20 by performing thermal caulking in which bonding and crimping are performed by applying heat and pressure. The monitoring device 40 may be fixed to the battery module 20 by a snap-fit structure using elastic deformation of a metal or resin material. External dimensions of the monitoring device 40 are set so as to satisfy a relationship of the dimension in the X direction>the dimension in Z direction>the dimension in Y direction when attached to the battery module 20. A space S1 is provided around the monitoring device 40. The space S1 is a space partially surrounded by the first wall surface 30a and the second wall surface 30b of the housing 30 and the wall surface 20a of the battery module 20. The monitoring device 40 is disposed with the smallest thickness in the Y direction among the XYZ directions. Even if the battery module 20 is configured by arranging a large number of battery cells 22 in the Y direction and is configured to be wide in the Y direction, the monitoring device 40 can be disposed in the space S1 in which the Y direction is minimized. Accordingly, the space S1 on the inner side of the first wall surface 30a of the housing 30 can be effectively used. The monitoring device 40 may be disposed at a position closer to an upper side in the Z direction than a lower side in the Z direction from a height center of the battery cell 22 on the wall surface 20a of the battery module 20. If most part of the monitoring device 40 is disposed on the upper side from the height center of the battery cell 22, the other part may be disposed on the lower side from the height center of the battery cell 22. In other words, the monitoring device 40 may be provided in such a manner that a region in which the arrangement position is located on the upper side from the height center of the battery cell 22 is larger than a region in which the arrangement position is located on the lower side. At this time, for example, the monitoring device 40 can be easily disposed from the upper side of the battery module 20, and the assemblability when the monitoring device 40 is disposed in the battery module 20 can be improved.

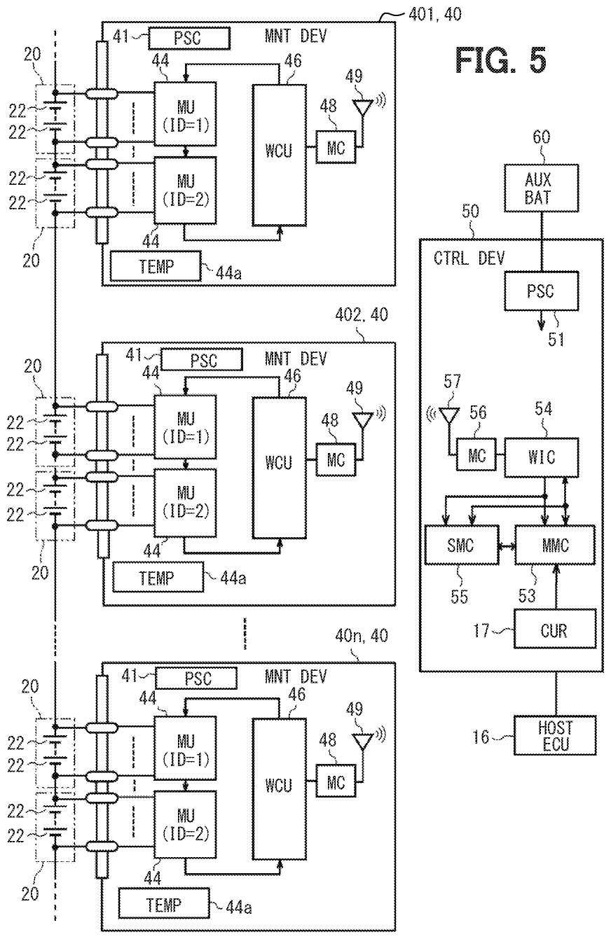

The control device 50 is attached to the outer end surface in the X direction of the battery module 20 located at the end portion in the X direction among all the battery modules 20. As illustrated in FIG. 5, each of the monitoring devices 40 includes an antenna 49 and the control device 50 includes an antenna 57, and the control device 50 and the monitoring devices 40 are wirelessly connected to each other.

If a structure in which the control device 50 is connected to the monitoring devices 40 by wires is adopted, it is necessary to connect harnesses between the monitoring devices 40 and the control device 50. For example, in a case where an operator extends harnesses into the space S1 on the inner side of the first wall surface 30a of the housing 30 to connect the monitoring devices 40 and the control device 50, the assemblability is poor and many man-hours are required. In this regard, since the monitoring devices 40 and the control device 50 are configured to be wirelessly connected to each other, even if the monitoring devices 40 are disposed in the minimum space S1, it is possible to dispose the monitoring devices 40 without deteriorating the assemblability.

Note that a fixing member for fixing the monitoring device 40 to the battery module 20 is preferably made of, for example, a non-magnetic material, whereby the performance of wireless communication can be improved. The components provided in the battery module 20 are preferably made of a nonmagnetic material, particularly when magnetic properties are not required.

The monitoring device 40 is fixed to the end surface of the battery module 20 in the Y direction. As illustrated in FIG. 2 and FIG. 3, the monitoring device 40 is connected with a detection line L. The detection line L is configured for each of the battery modules 20. The detection line L extends upward from an upper portion of the monitoring device 40 and is bent at an end portion of the battery module 20 to extend over the upper surfaces of the battery cells 22 in the Y direction. The detection line L indicates a harness for detecting a voltage between the positive electrode terminal 23 and the negative electrode terminal 24 of each of the battery cells 22.

The detection lines L extend in the Y direction along the upper surfaces of the battery cells 22 constituting one battery module 20. The detection line L extends between the bus bar covers 27 formed at both ends of each of the battery cells 22 in the X direction. The detection line L is electrically connected to the positive electrode terminal 23 and the negative electrode terminal 24 of each of the battery cells 22 by a core wire (not shown) extending from an intermediate position extending in the Y direction to both sides in the X direction.

### <Description of Structure of Housing 30>

As a countermeasure for EMC, the housing 30 is capable of reflecting electromagnetic waves, for example. EMC is an abbreviation for Electromagnetic Compatibility. The housing 30 includes a resin material and a metal having magnetic characteristics for reflecting electromagnetic waves, that is, a magnetic material. The housing 30 may include the resin material while the magnetic material covering the resin material or being embedded in the resin material. The housing 30 may be formed of a resin material, but may be covered by a chassis of the vehicle 10 for the countermeasure for EMC. The housing 30 may include carbon fiber. The housing 30 may include a material having a capability of absorbing electromagnetic waves instead of a capability of reflecting electromagnetic waves.

The wall surfaces 20a (see FIG. 2 and FIG. 4) located at ends of the battery modules 20 on one side in the Y direction extend in the X direction. The wall surfaces 20a may be covered with a reflecting member (for example, a metal or a magnetic material having magnetic properties) configured to reflect electromagnetic waves. The space S1 located on the inner side of the first wall surface 30a of the housing 30 is, for example, a space whose longitudinal and lateral dimensions in the YZ direction are about several mm to several cm to several tens of cm.

As described above, the space S1 is partially surrounded by the wall surfaces 20a of the battery modules 20 and the first wall surface 30a, the lower inner surface 30d, the upper inner surface 30c, and the second wall surface 30b of the housing 30. The space S1 is partially closed by a metal serving as the reflecting member, and is opened only to a space S1b in which the control device 50 is disposed. The space S1b is located on one side in the X direction and is adjacent to a third wall surface 30e located in a left direction in FIG. 4.

The monitoring devices 40 are disposed in the space S1. The monitoring devices 40 are periodically arranged in the X direction, for example, at equal intervals. In a case where the space S1 is covered with metal, the space S1 constitutes a waveguide space similar to a so-called rectangular waveguide. As illustrated in FIG. 4, the housing 30 constitutes a space closed by the first wall surface 30a, the second wall surface 30b, the third wall surface 30e, and a fourth wall surface 30f in plan view. The first wall surface 30a faces the fourth wall surface 30f, and the second wall surface 30b faces the third wall surface 30e. At this time, a propagation space of the electromagnetic wave when the control device 50 and the monitoring devices 40 wirelessly communicate with each other has an L-shape in plan view. A wireless electromagnetic wave radiated by the control device 50 is reflected by the first wall surface 30a and propagated to the space S1, and is reflected by the third wall surface 30e and propagated to the space S1 to reach each of the monitoring devices 40. A wireless electromagnetic wave radiated by each of the monitoring devices 40 propagates in the space S1, is reflected by the first wall surface 30a, and reaches the control device 50, and propagates in the space S1, is reflected by the third wall surface 30e, and reaches the control device 50. Accordingly, when the control device 50 and the monitoring devices 40 wirelessly communicate with each other, the radio wave propagates in an L-shaped propagation path including the space S1.

In the present embodiment, the propagation path of the electromagnetic wave when the control device 50 and the monitoring devices 40 wirelessly communicate with each other also includes the space S1a illustrated in FIG. 3. The space S1a is sandwiched between bus bar covers 27 disposed at both ends in the X direction of the battery cells 22, and is provided so as to be surrounded by the top surface 11a of the battery pack 11, that is, the upper inner surface 30c of the housing 30 and the upper surfaces of the battery cells 22. The space S1a is provided to have a gap between the upper inner surface 30c of the housing 30 and the bus bar covers 27. The space S1a extends in the X direction along a lower side of the upper inner surface 30c of the housing 30. The space S1a extends in the X direction to be connected with the space S1b in which the control device 50 is disposed. As described above, since the spaces S1a and S1b can serve as propagation paths of the wireless electromagnetic waves between the control device 50 and the monitoring devices 40, the number of communication paths can be increased in addition to the above-described L-shaped propagation path. In the above description, the space S1a is provided with a gap between the upper inner surface 30c of the housing 30 and the bus bar covers 27, but this gap may not be provided.

The housing 30 includes a hole through which an accommodation space of the battery pack 11 communicates with an external space outside the accommodation space. The hole is used for ventilation, energization of power lines and signal lines, and the like. In a configuration having the hole, a covering portion (not shown) that covers the hole may be provided. The covering portion is formed of, for example, a connector, an electromagnetic shielding member, or a sealing material. The covering portion closes a part or all of the hole between the accommodation space of the battery pack 11 and the external space outside the accommodation space.

The covering portion includes, for example, a metal material having magnetic properties. The covering portion may include a resin material while the magnetic material covering the resin material or being embedded in the resin material. The covering portion may include carbon fiber.

The hole of the housing 30 may be covered by an element accommodated in the accommodation space of the housing 30 without providing the covering portion additionally. The power lines and the signal lines may be disposed across the accommodation space and the external space while being held by an electrically insulating member forming a part of the wall of the housing 30.

### <Modification of Arrangement Mode of Monitoring Devices 40 and Control Device 50>

The attachment structure of the monitoring devices 40 and the control device 50 is not limited to the structure illustrated in FIG. 2. For example, the monitoring devices 40 may be respectively attached to the battery modules 20 inside the housing 30, but the control device 50 may be attached to an outer surface of the housing 30. For example, an attachment structure in which a wall surface of the housing 30 is provided in a region where the monitoring devices 40 and the control device 50 face each other may be employed. In this case, although a propagation environment of radio waves between the monitoring devices 40 and the control device 50 deteriorates as compared with the attachment structure illustrated in FIG. 2, the attachment structure is sufficient to execution of a communication process between the monitoring devices 40 and the control device 50.

The antenna 49 included in each of the monitoring devices 40 is disposed so as not to overlap with the bus bar units 25 in the Z direction, that is, so as to protrude more than the bus bar units 25 in the Z direction. The antenna 57 of the control device 50 may be provided so as to protrude more than the bus bar units 25 in the Z direction. The antenna 57 connected to the control device 50 may be disposed, for example, at the same height in the Z direction as the antenna 49 of each of the monitoring devices 40. The arrangement relationship between the antennas 49 and 57 is not limited to the above-described relationship.

### <Modification of Arrangement Structure of Battery Modules 20>

In the present embodiment, the battery modules 20 in each of which the battery cells 22 are packed are prepared and directly stored in the housing 30. However, a so-called battery module-less structure may be employed. For example, as referred to as “cell to pack”, modularization of the battery cells 22 may be omitted, and the battery cells 22 may be directly stored in the battery pack 11.

As referred to as “battery module to platform”, the battery modules 20 may be directly stored in a frame or a platform of the vehicle 10. As also referred to as “cell to chassis”, the battery cells 22 may be directly packed on a chassis of the vehicle 10 as part of the vehicle body structure. Since the arrangement positions of the control device 50 and the monitoring devices 40 are fixed, the control device 50 and the monitoring devices 40 are less likely to be affected by temporal communication position variation such as communication process between smartphones and tablet terminals.

### <Description of Configurations of PCU14, Motor 15, and Host ECU 16>

A part or all of the host ECU 16 and the control device 50 may be integrated, or may be provided separately. The PCU 14 illustrated in FIG. 1 executes bidirectional power conversion between the battery pack 11 and the motor 15 in accordance with a control signal from the host ECU 16. The PCU 14 includes, for example, an inverter that drives the motor 15, and a converter that boosts a DC voltage supplied to the inverter to be equal to or higher than an output voltage of the battery pack 11.

The motor 15 is an AC rotating electric machine, and is, for example, a three-phase AC synchronous motor in which a permanent magnet is embedded in a rotor. The motor 15 is driven by the PCU 14 to generate a rotational driving force, and the driving force generated by the motor 15 is transmitted to driving wheels of the vehicle 10. On the other hand, during braking of the vehicle 10, the motor 15 operates as a generator and performs regenerative power generation. The electric power generated by the motor 15 is supplied to the battery pack 11 through the PCU 14 and stored in the assembled battery 12 of the battery pack 11.

The host ECU 16 includes a CPU, a ROM, a RAM, a memory such as a nonvolatile semiconductor storage device, and an input/output port for inputting and outputting various signals. A processing program to be executed by the host ECU 16 is stored in the memory, and the CPU executes the program stored in the memory. The memory is used as a non-transitory tangible storage medium. The control device 50 receives information on a cell voltage of each of the battery cells 22 of the assembled battery 12 from the monitoring devices 40 of the battery pack 11, measures a state of charge (SOC), and controls the PCU12 to control driving of the motor 15 and charging and discharging of the battery pack 11.

A current sensor (CUR) 17 (see FIG. 5) is configured in or connected to the control device (CTRL DEV) 50, and the current sensor 17 measures the current flowing through the assembled battery 12 in which the battery cells 22 are connected in series. Thus, the current flowing through the entire assembled battery 12 can be measured. The control device 50 and the host ECU 16 can acquire information on the current flowing through the assembled battery 12 and the battery cells 22 from sensing information of the current sensor 17.

Here, a configuration in which the current sensor 17 is connected to the control device 50 is illustrated, but the current sensor 17 may be connected to the host ECU 16, and the host ECU 16 may acquire information on the current flowing through the assembled battery 12 by the current sensor 17. Since the control device 50 and the host ECU 16 can be communicatively connected to each other, the information of the current flowing through the assembled battery 12 can be shared with each other regardless of which configuration acquires the information of the current from the current sensor 17.

Hereinafter, specific configurations of the monitoring devices 40 and the control device 50 will be described.

### <Specific Configuration Example of System of Monitoring Devices 40>

As illustrated in FIG. 5, each of the monitoring device (MNT DEV) 40 includes a power supply circuit (PSC) 41, a plurality of monitoring units (MU) 44, a wireless communication unit (WCU) 46, a matching circuit (MC) 48, and an antenna 49. Each of the monitoring devices 40 is configured by mounting the monitoring units 44 and the wireless communication unit 46 on an identical substrate. That is, the number of monitoring units 44 is larger than the number of wireless communication unit 46 on the identical substrate. The power supply circuit 41 generates an operation voltage using the voltage supplied from the battery modules 20 and supplies the generated voltage to the monitoring units 44 and the wireless communication unit 46.

A temperature sensor (TEMP) 44a is directly mounted on the battery module 20 or is mounted on the monitoring device 40. The monitoring unit 44 receives a sensor signal from the temperature sensor 44a and measures temperature information of the battery module 20 as battery-related information. If the temperature sensor 44a is mounted on the monitoring device 40 and a temperature of the monitoring device 40 is measured by the temperature sensor 44a, it is possible to measure the temperature of the battery cells 22 depending on the measured temperature. Accordingly, the temperature information depending on the temperature of the battery cells 22 can be measured as the battery-related information.

Each of the monitoring units 44 receives sensor signals based on the cell voltages of the battery cells 22 for each of the battery modules 20. The monitoring unit 44 includes an ASIC monitoring IC including a multiplexer and an ND converter. ASIC is an abbreviation for Application Specific Integrated Circuit. The monitoring unit 44 selectively receives information on the cell voltage of a necessary battery cell 22 among the battery cells 22 by a multiplexer, converts the information into digital data by the ND converter, and then executes necessary process. Accordingly, the monitoring unit 44 acquires the information on the cell voltage as the battery-related information.

The monitoring unit 44 executes failure diagnosis of a circuit portion or the detection line L of the monitoring device 40 and monitors diagnosis information. The monitoring unit 44 executes, for example, a self-diagnosis process of determining whether or not the detection line L is disconnected, and acquires this diagnosis information as battery-related information. Specifically, the monitoring unit 44 determines whether or not the cell voltages acquired from the two detection lines L are in the normal range, thereby acquiring the self-diagnosis result of determining whether or not the detection lines L are disconnected as the battery-related information.

Accordingly, the monitoring unit 44 of the monitoring device 40 can acquire, as the battery-related information, the voltage information related to the assembled battery 12, the temperature information of the assembled battery 12 or the monitoring device 40, the diagnosis information diagnosed in relation to the assembled battery 12 or the monitoring device 40, and the like.

Although the monitoring units 44 are configured as integrated circuits in the monitoring device 40, the monitoring units 44 may be configured to separately acquire the voltage information, the temperature information, and the diagnosis information. One monitoring unit 44 may be configured to acquire information of at least two or more types of data among the voltage information, the temperature information, and the diagnosis information.

The wireless communication unit 46 and the monitoring units 44 are connected in daisy-chain fashion through a bus. ID information (for example, 1, 2 . . . ) is assigned in advance to each of the monitoring units 44, and each of the monitoring units 44 stores the ID information in advance in a built-in nonvolatile memory. When the wireless communication unit 46 transmits information to the monitoring units 44, the wireless communication unit 46 transmits the information to be transmitted together with the ID information of each of the monitoring units 44 as an overhead (header, footer), so that the information can be individually transmitted to the monitoring units 44. In addition, when the wireless communication unit 46 transmits the same information to all the monitoring units 44, the wireless communication unit 46 can broadcast the information by transmitting the information through the bus.

When the monitoring unit 44 of the monitoring device 40 acquires the battery-related information described above, the monitoring unit 44 stores the battery-related information in a memory built in the ASIC or a memory mounted in the wireless communication unit 46. The wireless communication unit 46 includes a wireless IC together with a so-called microcontroller, and wirelessly communicates various data with the control device 50 through the matching circuit 48 and the antenna 49 by the wireless IC.

The wireless communication unit 46 is provided as a control circuit having a function of controlling battery monitoring information of the monitoring unit 44 or a schedule of self-failure diagnosis. When the wireless communication unit 46 of the monitoring device 40 receives the battery-related information such as the battery information, the temperature information, or the diagnosis information from the monitoring unit 44, the wireless communication unit 46 transmits the battery-related information to the control device 50.

The matching circuit 48 and the antenna 49 of the monitoring device 40 represent a physical interface for converting an output signal of the wireless communication unit 46 into a radio wave and radiating the radio wave to the space S1, and for receiving the radio wave propagated in the space S1 and inputting the radio wave to the wireless communication unit 46.

The wireless communication unit 46 of the monitoring device 40 receives information such as various command information from a wireless IC 54 of the control device 50. The wireless IC of the wireless communication unit 46 represents a communication device that controls, for example, a data size, a format, a schedule and error detection in communication between the monitoring devices 40 and the control device 50. If the wireless communication unit 46 detects an error when receiving the information, the wireless communication unit 46 requests the wireless IC 54 of the control device 50 to retransmit the information.

In the present embodiment, the wireless communication unit 46 includes both the microcontroller and the wireless IC. However, the functions of the microcontroller and the wireless IC may be separately implemented. When the wireless communication unit 46 is configured by the wireless IC, the microcontroller may be interposed between the wireless communication unit 46 and the monitoring unit 44. At this time, the microcontroller mounted on the monitoring device 40 may manage the acquisition schedule or the transmission schedule of the battery-related information by the monitoring units 44.

### <Specific Configuration Example of System of Control Device 50>

The control device 50 includes a power supply circuit (PSC) 51, a main microcontroller 53 (MMC), the wireless IC (WIC) 54, a sub microcontroller (SMC), a matching circuit (MC) 56, and an antenna 57. The power supply circuit 51 of the control device 50 generates an operating voltage using a voltage supplied from an auxiliary battery (AUX BAT) 60, and supplies the operating voltage to the wireless IC 54, the sub microcontroller 55, and the main microcontroller 53.

The matching circuit 56 and the antenna 57 of the control device 50 represent a physical interface for converting a signal output from the wireless IC 54 into a radio wave and radiating the radio wave to the space S1, and for receiving the radio wave propagated in the space S1 and inputting the radio wave to the wireless IC 54.

The wireless IC 54 of the control device 50 receives the battery-related information from the wireless communication unit 46 of each of the monitoring devices 40 and transmits the information to the main microcontroller 53 of the control device 50. The wireless IC 54 of the control device 50 receives data transmitted from the main microcontroller 53 and transmits the data to the wireless communication unit 46 of each of the monitoring devices 40 by unicast communication or broadcast communication. The wireless IC 54 represents a communication device that controls a data size, a format, a schedule, error detection in communication between each of the monitoring devices 40 and the control device 50. The wireless IC 54 has a function of making a retransmission request to each of the monitoring devices 40 when detecting an error in data transmitted from the wireless communication unit 46 of each of the monitoring device 40.

The main microcontroller 53 of the control device 50 uses information such as the voltage information and the temperature information included in the battery-related information transmitted from the wireless communication unit 46 to calculate SOC, diagnosis information, and the like serving as a state index of the battery cell 22, and transmits the SOC, the diagnosis information, and the like to the host ECU 16. The main microcontroller 53 controls switching of an ignition on/off state and control of equalizing the voltages of the battery cells 22.

The main microcontroller 53 transmits information such as a control signal to the wireless communication unit 46 of each of the monitoring devices 40 through the wireless IC 54 by wireless communication, and controls the operation state of each of the monitoring device 40. The sub microcontroller 55 of the control device 50 monitors data between the wireless IC 54 and the main microcontroller 53, and monitors an operation state of the main microcontroller 53. The sub microcontroller 55 may monitor the operation state of the wireless IC 54.

In the present embodiment, the control device 50 includes the sub microcontroller 55, and the sub microcontroller 55 monitors the data between the wireless IC 54 and the main microcontroller 53, and monitors the operation state of the main microcontroller 53. However, the configuration of the control device 50 is not limited to this example. For example, the control device 50 may not include the sub microcontroller 55.

The main microcontroller 53 of the control device 50 may manage the acquisition schedule of the battery monitoring information or the communication schedule of each of the monitoring units 44 instead of the wireless communication unit 46. The main microcontroller 53 may manage the acquisition schedule of the self-diagnosis information of each of the monitoring devices 40.

In the present embodiment, an example has been described in which the main microcontroller 53 of the control device 50 calculates the SOC, the diagnosis information, and the like serving as the state index of the battery cell 22 using the battery-related information such as the voltage information and the temperature information transmitted from the wireless communication unit 46, and transmits the SOC, the diagnosis information, and the like to the host ECU 16. However, the calculation of the battery-related information is not limited to this example.

For example, the wireless communication unit 46 of each of the monitoring devices 40 may calculate the SOC, the diagnosis information, and the like serving as the state index of the battery cell 22 using the battery-related information acquired by the monitoring units 44, and transmit the calculation result to the wireless IC 54 of the control device 50. In addition, the wireless communication unit 46 of each of the monitoring devices 40 may perform the abnormality diagnosis of the battery cells 22 or the monitoring units 44 using the calculation result, and may transmit the result of the abnormality diagnosis to the wireless IC 54 of the control device 50. The battery-related information acquired by the monitoring unit 44 of each of the monitoring devices 40 may be calculated by the wireless communication unit 46 of each of the monitoring devices 40.

### <Wireless Communication Method>

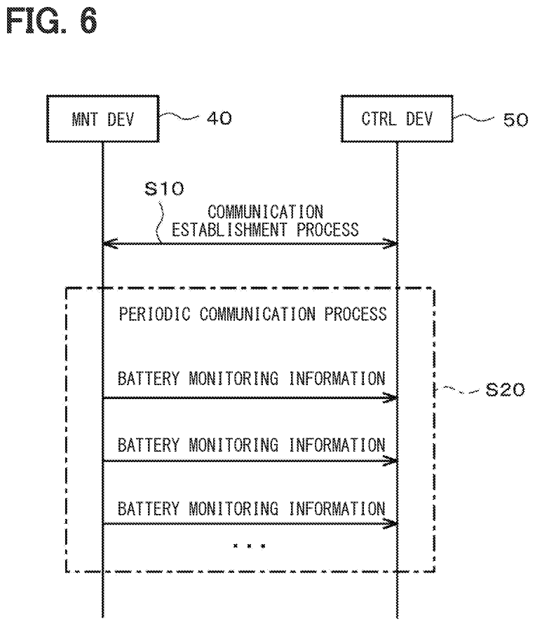

A wireless communication method between the control device 50 and the monitoring devices 40 will be described with reference to FIGS. 6 to 8. In the battery monitoring system 1 according to the present embodiment, the monitoring devices 40 are connected to the control device 50 via a star network in which the control device 50 is a central hub, and packet communication is possible between the monitoring devices 40 and the control device 50. A packet includes an access address for determining a communication partner, a protocol data unit indicating data to be transmitted and received in an upper layer, and an error detection code by a cyclic check code (CRC). In the battery monitoring system 1, the number of communication nodes is three or more.

The control device 50 may measure, for example, the number of communication errors, the number of times of occurrence of retransmission of communication data, and a received signal strength indicator (RSSI) with each of the monitoring devices 40 as communication record information in the arrangement environment described above. The control device 50 may narrow down a frequency band having a good communication record in advance based on the communication record information, store the narrowed frequency band in an internal memory of the wireless IC 54, and select a frequency band from the frequency bands stored in the memory to execute communication.

In addition, an external communication unit such as a data communication module (DCM) may be separately mounted on the vehicle 10, and the data communication module may be configured to perform data communication with the outside. In this case of the vehicle 10, it is desirable to execute communication using a frequency band different from the frequency band used in the data communication battery module.

The control device 50 individually establishes communication with each of the monitoring devices 40 and wirelessly communicates information. Hereinafter, wireless communication between one control device 50 and one monitoring device 40 will be described, but the control device 50 executes a similar process with all of the monitoring devices 40.

As illustrated in FIG. 6, the monitoring device 40 and the control device 50 execute a communication establishment process in S10. The communication establishment process is executed, for example, when the monitoring device 40 is activated and when the control device 50 is activated. When starting the vehicle 10, a user operates the ignition switch from OFF to ON, and at this time, a start signal is given to the control device 50. When the control device 50 is activated, the communication establishment process is executed between the control device 50 and all the monitoring devices 40. The communication establishment process is a process necessary for unicast communication and is not necessary for broadcast communication. When the communication establishment process is succeeded, the control device 50 continues a periodic communication process in S20 of FIG. 5 with the monitoring device 40 with which communication is established.

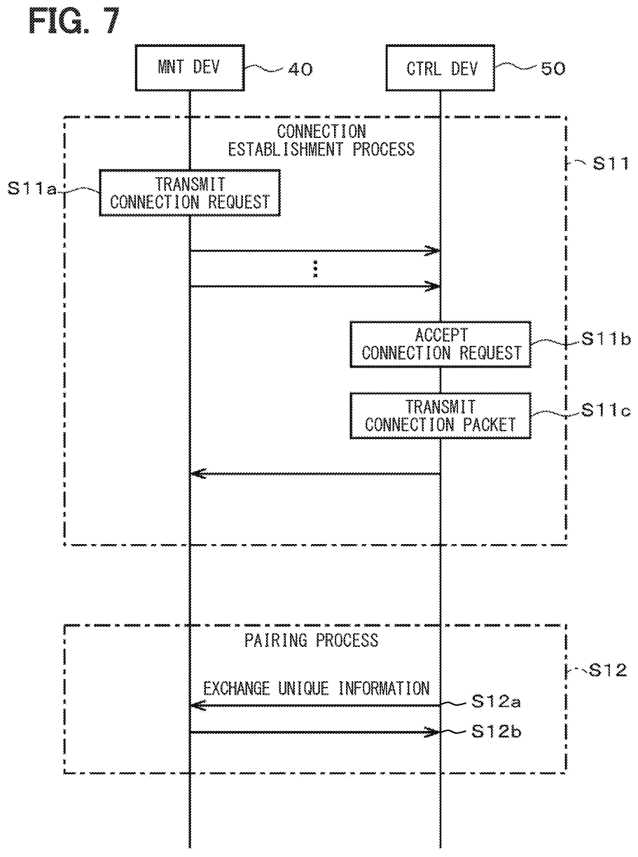

As shown in FIG. 7, the communication establishment process can be divided into a connection establishment process shown in S11 and a pairing process shown in S12. The monitoring device 40 and the control device 50 execute a connection establishment process in S11. The connection establishment process starts when the monitoring device 40 transmits a connection request packet in S11a.

When the monitoring device 40 transmits the connection request packet to the control device 50 in S11a, the control device 50 receives the connection request packet in S11b. When the monitoring device 40 executes an advertising operation, the connection request packet is referred to as an advertisement packet. The connection request packet includes, for example, ID information of the monitoring device 40 and ID information of the control device 50. The monitoring device 40 periodically transmits the connection request packet until connection establishment is completed.

The control device 50 detects the monitoring device 40 by receiving the connection request packet through a connection accepting operation, and then the control device 50 transmits a connection packet as a response to the detected monitoring device 40 in S11c. When the monitoring device 40 receives the connection packet, the monitoring device 40 can recognize establishment of connection with the control device 50. Accordingly, the target monitoring device 40 can establish connection with the control device 50. When the connection establishment is completed, the monitoring device 40 stops transmitting the connection request packet.

When the connection establishment process ends, the pairing process is subsequently executed. The pairing process is a process for encrypted data communication, and includes a process of exchanging unique information as illustrated in S12a and S12b. In this exchange process, unique information held by each other is exchanged. Encryption using the unique information can be performed after execution of the exchange process in S12a and S12b. The unique information is, for example, key information or information for generating a key. Accordingly, the communication establishment process shown in S10 of FIG. 5 ends.

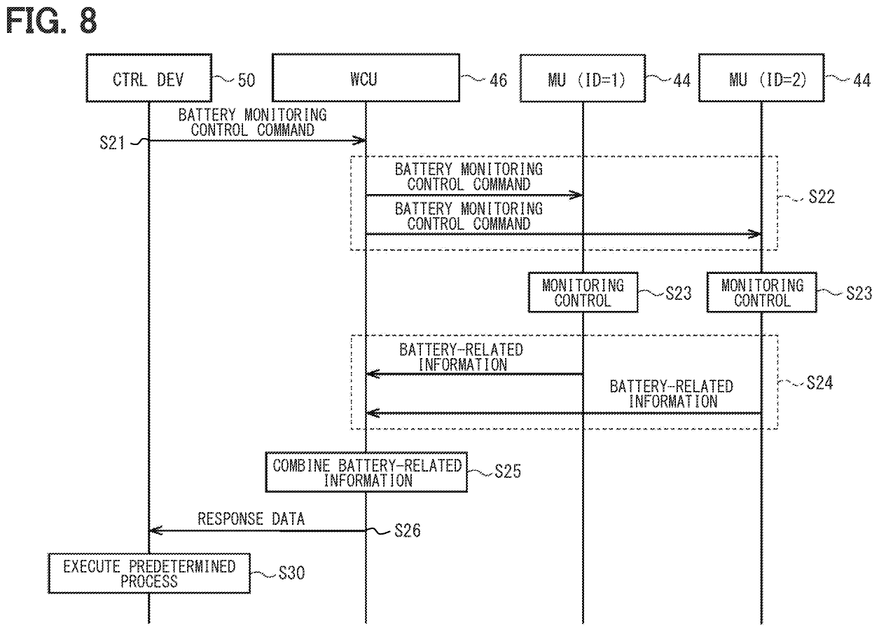

When the monitoring device 40 and the control device 50 complete the communication establishment process in S10 of FIG. 6, the monitoring device 40 and the control device 50 execute the periodic communication process in S20 of FIG. 6. As illustrated in FIG. 8, in S21, the control device 50 transmits instruction information of a battery monitoring control command to the wireless communication unit 46 of the monitoring device 40 for which the communication establishment process has been completed. The control device 50 transmits request information including, for example, an acquisition request of the battery-related information of the monitoring unit 44 and a transmission request of the acquired information as the battery monitoring control command.

When the instruction information of the battery monitoring control command is received, in S22, the wireless communication unit 46 of the monitoring device 40 transmits the instruction information of the battery monitoring control command to the monitoring units 44 to transmit an acquisition instruction of the battery-related information. The wireless communication unit 46 simultaneously transmits the acquisition instruction of the battery-related information to the monitoring units 44 by broadcasting the battery monitoring control command to the monitoring units 44.

Although the wireless communication unit 46 simultaneously transmits the instruction information of the battery monitoring control command to the monitoring units 44 in S22, the present disclosure is not limited this example. For example, the wireless communication unit 46 may add ID information of the monitoring units 44 to a packet and individually transmit the instruction information.

When each of the monitoring units 44 receives the instruction information of the acquisition instruction, in S23, each of the monitoring units 44 executes a battery monitoring control such as a sensing process of the voltage of the battery cells 22 and/or the failure diagnosis. Each of the monitoring units 44 acquires the voltage information, the temperature information, and/or the diagnosis information of each of the battery cells 22 as the battery-related information when executing the battery monitoring control. Next, in S24, each of the monitoring units 44 transmits the acquired battery-related information to the wireless communication unit 46 as a response. Here, the monitoring units 44 transmit signals to the wireless communication unit 46 in synchronization with each other through the bus.

When the wireless communication unit 46 receives the information acquired by the monitoring units 44, in S25, the wireless communication unit 46 combines these pieces of battery-related information. Here, combining means combining into one packet or a plurality of continuous packets. The wireless communication unit 46 generates response data based on the battery-related information combined in S25 and transmits the response data to the control device 50. The wireless IC 54 of the control device 50 receives the response data in S26.

<Description of Retransmission Process when Communication Error Occurs>

Here, a process that is executed when an error occurs in data received by the wireless IC 54 will be described. When the wireless communication unit 46 of the monitoring device 40 transmits a packet of the battery-related information to the control device 50, the wireless IC 54 of the control device 50 extracts a cyclic check code (CRC) for error detection from the received packet and detects an error. The wireless IC 54 receives the battery monitoring information when no error is detected in the packet. Then, the wireless IC 54 transmits the battery-related information to the main microcontroller 53, and the main microcontroller 53 executes a predetermined process.

On the other hand, when detecting an error in the packet, the wireless IC 54 requests the monitoring device 40 to retransmit the battery-related information. When the control device 50 makes a retransmission request to the wireless communication unit 46 of the monitoring device 40, the wireless communication unit 46 of the monitoring device 40 retransmits the previously transmitted battery monitoring information to the control device 50. For example, when the propagation environment of radio waves deteriorates and communication errors are repeated, the wireless communication unit 46 and the monitoring unit 44 of the monitoring device 40 are likely to have insufficient resources for executing other tasks. In this case, even if there is a request for acquiring the next battery-related information from the control device 50, the monitoring device 40 acquires the battery-related information and transmits the battery-related information at a delayed timing. Therefore, it is desirable to minimize communication errors.

### <Description of Process of Control Device 50>

Next, a process executed by the control device 50 will be described. In S30, the main microcontroller 53 of the control device 50 refers to the response data received by the wireless IC 54, and executes a predetermined process based on the response data. In S30, for example, the control device 50 executes the predetermined process based on a plurality of pieces of the battery monitoring information acquired within a predetermined period.

For example, the control device 50 of the present embodiment acquires the value of the cell voltage of each of the battery cells 22 from a plurality of pieces of battery-related information acquired from the monitoring devices 40 during the predetermined period, and further acquires the value of the cell current through the current sensor 17 connected in series to the battery cells 22. The control device 50 estimates an internal resistance and an open circuit voltage of each of the battery cells 22 based on the cell voltage and the cell current.

The control device 50 can calculate a SOH based on the estimated internal resistance. SOH is an abbreviation of States Of Health, and is an index indicating a deterioration state of a battery. The control device 50 can detect an abnormality of the battery cell 22 by comparing the open circuit voltages of the battery cells 22 with each other and determining whether a difference between the open circuit voltages is within a certain range. The “predetermined process” is mainly executed by the main microcontroller 53 in the present embodiment, but may be executed by another configuration in the control device 50. In this way, a sequence for one cycle can be executed.

### <Modification of Sequence in FIG. 8>

The control device 50 may process other communication when it is assumed that there is an idle time between the transmission of the instruction information of the battery monitoring control command to the wireless communication unit 46 of the monitoring device 40 in S21 and the reception of the response data in S26.

The control device 50 periodically transmits the instruction information of the battery monitoring control command according to a schedule control. However, for example, there may be a case where the battery-related information corresponding to the battery monitoring control command in the previous cycle is not yet received even though the timing of transmitting the instruction information of the battery monitoring control command in the current cycle has come in S21. In such a case, the control device 50 may receive the battery-related information in the previous cycle before receiving the battery-related information in S26 in the current cycle and after transmitting the instruction information of the battery monitoring control command in S21 in the current cycle.

Further, for example, the control device 50 may transmit the instruction information of the battery monitoring control command in the next cycle to the wireless communication unit 46 of the monitoring device 40 before receiving the response data of the battery-related information according to the instruction information of the battery monitoring control command in the current cycle in S26 and ending the current cycle.

### <Wireless Transmission Data>

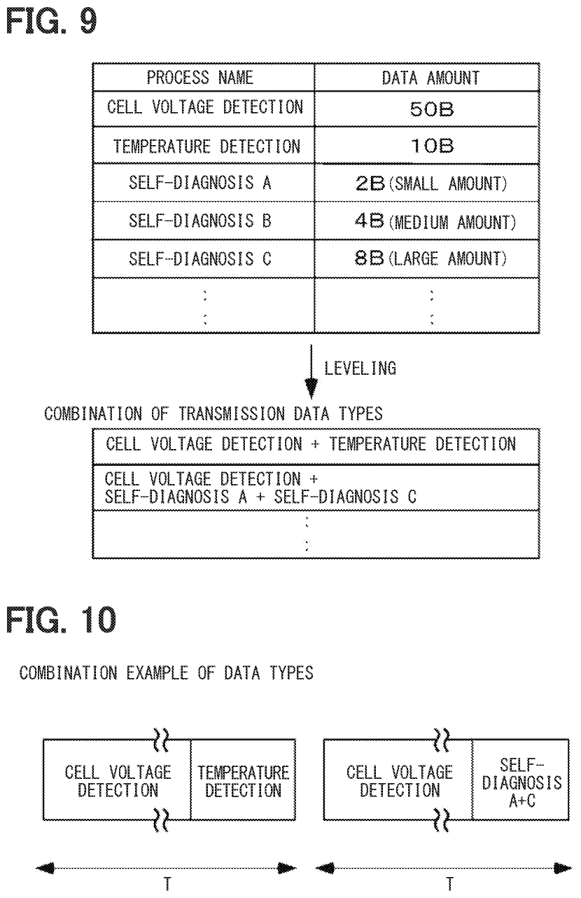

Next, contents of data wirelessly transmitted from the wireless communication unit 46 to the control device 50 will be described with reference to FIG. 9. As described above, the monitoring device 40 acquires a large variety of data acquired by the monitoring units 44 and transmits the data to the control device 50. Accordingly, the control device 50 can perform comprehensive process based on the received data. Therefore, it is desirable that the wireless communication unit 46 of the monitoring device 40 efficiently wirelessly transmits the various data to the control device 50.

The wireless communication unit 46 of the monitoring device 40 may select different types of information for each of the monitoring units 44 among the battery-related information acquired by the monitoring units 44 and wirelessly transmit the selected information collectively. Here, collective wireless transmission means transmission in one packet or continuous transmission of a plurality of packets. As described above, examples of the data type of the battery-related information include the voltage information of the cell voltage of the battery cells 22 of the assembled battery 12, the temperature information of the assembled battery 12 or the monitoring device 40, and the diagnosis information diagnosed in relation to the assembled battery 12 or the monitoring device 40.

FIG. 9 relatively illustrates the amount of data for each type of data. For example, a data amount of the voltage information of the cell voltage is 50 bytes, a data amount of the temperature information is 10 bytes, and the data amount of the voltage information is about several times the data amount of the temperature information. This is because the monitoring unit 44 is provided for each of the battery modules 20, and the data amount of the voltage information of the battery cells 22 to be monitored is relatively larger than the temperature information and the diagnosis information.

A data amount of a self-diagnosis A indicating the presence or absence of the disconnection of the detection lines L of the monitoring units 44 is 2 bytes, a data amount of a self-diagnosis B indicating the presence or absence of the abnormality of the monitoring units 44 is 4 bytes, and a data amount of a self-diagnosis C indicating an abnormality determination content of the monitoring units 44 is 8 bytes. As described above, the amount of data varies depending on the type of data. These data amounts exemplify data amounts for relative description, and are not limited to the examples illustrated in FIG. 9.

The wireless communication unit 46 may wirelessly transmit a combination of types of data having a smaller data amount than a combination of types of data having the largest data amount among the battery-related information acquired by the monitoring units 44. Here, “wirelessly transmit a combination” means wirelessly transmit the combination of data in one packet, or wirelessly transmit the combination of data in a plurality of continuous packets.

As illustrated, when a plurality of pieces of voltage information of the cell voltages of the battery cells 22 acquired by each of the plurality of monitoring units 44 is combined, the data amount is maximized. Therefore, when the voltage information of the cell voltages acquired by each of the monitoring units 44 is combined, the data amount increases. In this way, the plurality of pieces of voltage information of the cell voltages may be combined. However, when the data having the largest data amount are combined, the time required for communication increases, and thus a cycle of communication becomes long. In a case where the cycle is set to be long and constant so that communication can be performed even in a combination of types of data having a large amount of data, when communication is performed in a combination of types of data having a small amount of data in the subsequent cycles, a time required for communication is significantly shorter than the cycle of communication set to be constant, and a useless time is generated in the cycle of communication. When the voltage information acquired by one monitoring unit 44 is wirelessly transmitted in combination with another type of data, the total amount of data to be transmitted collectively can be reduced as compared with a case of wirelessly transmitting a combination of pieces of battery-related information having the largest amount of data. As a result, communication errors in wireless communication can be restricted.

Further, the data amount of the temperature information is larger than that of the diagnosis information. Therefore, the wireless communication unit 46 may wirelessly transmit the voltage information or the temperature information in combination with the diagnosis information. Such a combination of pieces of information may be determined in advance and stored in the built-in memory of the wireless communication unit 46. It is desirable that the wireless communication unit 46 determines target data to be transmitted collectively by combining the types of data with reference to the content of the combination and wirelessly transmits the target data collectively. Here, “wirelessly transmitting collectively” means wireless transmitting data put by one packet, or wirelessly transmitting data by a plurality of continuous packets.

Among the types of data exemplified as described above, as illustrated on the left side of FIG. 10, the voltage information and the temperature information of the battery cells 22 may be combined and wirelessly transmitted collectively. As illustrated on the right side of FIG. 10, the voltage information of the battery cells 22, the diagnosis information of the self-diagnosis A, and the diagnosis information of the self-diagnosis C may be combined and wirelessly transmitted collectively.

As described above, the wireless communication unit 46 selects different types of information for each of the monitoring units 44 and wirelessly transmits the information collectively. Thus, it is possible to reduce the total amount of data wirelessly transmitted collectively. As a result, it is possible to restrict the communication error rate of wireless communication. Therefore, it is possible to restrict a decrease in the number of times of monitoring the battery.

The wireless communication unit 46 may wirelessly transmit the battery-related information acquired by the plurality of monitoring units 44 in such a manner that the total amount of data to be wirelessly transmitted collectively is within a predetermined range by combining the types of data of the battery-related information. In other words, the type of data may be combined with the amount of data that can be transmitted within a time of the predetermined one cycle or less and wirelessly transmitted. Since the total amount of data can be within the predetermined range when wirelessly transmitting collectively, the total amount of data to be wirelessly transmitted collectively can be reduced. As a result, the error rate of wireless transmission can be reduced.

The wireless communication unit 46 may change the battery-related information to be wirelessly transmitted according to a reading time of the battery-related information acquired by the plurality of monitoring units 44. When each of the monitoring units 44 acquires the battery-related information, each of the monitoring units 44 stores the battery-related information in the built-in memory and further transmits the battery-related information to the wireless communication unit 46. At this time, the time for which each of the monitoring units 44 reads the battery-related information depends on the data amount of the battery-related information and changes in proportion to the data amount.

When the wireless communication unit 46 receives the battery-related information from each of the monitoring units 44, the wireless communication unit 46 stores the battery-related information in the built-in memory. The wireless communication unit 46 transmits the battery-related information stored in the built-in memory to the control device 50 at a scheduled timing. At this time, the reading time for the wireless communication unit 46 to read the battery-related information from the built-in memory depends on the data amount of the battery-related information and changes in proportion.

Therefore, the wireless communication unit 46 may select and wirelessly transmit the battery-related information by avoiding a combination in which the reading time of the battery-related information is long and by avoiding a combination in which the total amount of data is large. Accordingly, the total amount of data to be wirelessly transmitted collectively can be adjusted, and the total amount of data to be wirelessly transmitted collectively can be reduced. As a result, the error rate of wireless communication can be reduced.

### <First Example of Transmission Data>

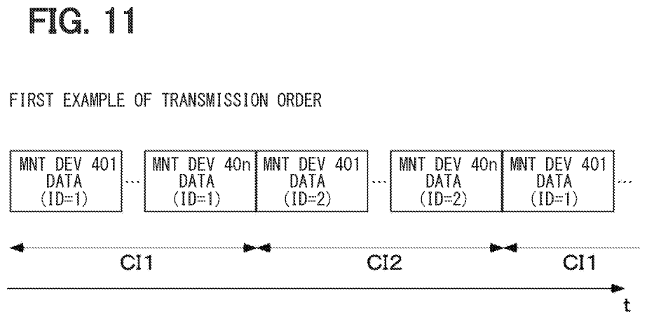

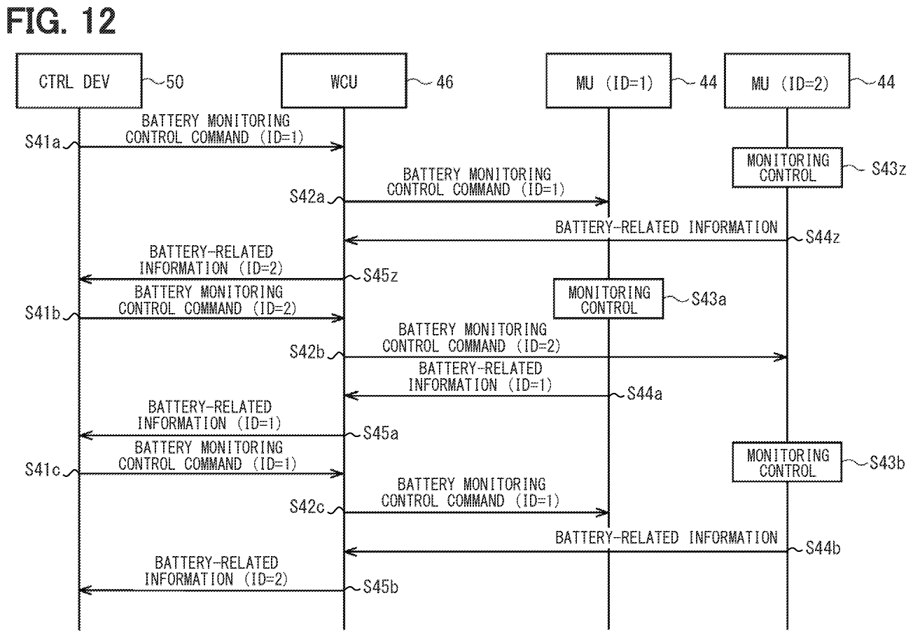

An example of transmission data will be described below. As illustrated in FIG. 11 and FIG. 12, the wireless communication unit 46 of each of the monitoring devices 40 (401 . . . 40n) may wirelessly transmit the battery-related information of the plurality of monitoring units 44 at different timings.

When the control device 50 manages the schedule of wireless transmission by the monitoring devices 40, each of the monitoring devices 40 performs wireless transmission during a time allocated according to the schedule. For example, as illustrated in FIG. 11, the monitoring devices 40 (401 . . . 40n) sequentially transmit the battery-related information acquired by the monitoring units 44 preset to ID=1 to the control device 50.

In the next cycle C12, the monitoring devices 40 (401 . . . 40n) sequentially transmit the battery-related information acquired by the monitoring units 44 preset to ID=2 to the control device 50. Here, only two examples of IDs=1 and 2 are illustrated. Therefore, in the next cycle C11, the monitoring devices 40 (401 . . . 40n) sequentially transmit the battery-related information acquired by the monitoring units 44 preset to ID=1 to the control device 50.

Here, only two examples of IDs=1 and 2 are shown, but the present disclosure is not limited thereto. For example, the present disclosure can also be applied to a case where each of the monitoring devices 40 (for example, 401 . . . 40n) includes a large number of monitoring units 44 preset to three or more in total, such as ID=1, 2, 3 . . . . The monitoring devices 40 (401 . . . 40n) may periodically and sequentially transmit the battery-related information acquired by the monitoring unit 44 assigned with IDs=1, 2, and 3 . . . to the control device 50.

As illustrated in FIG. 12, the control device 50 instructs the wireless communication unit 46 to outputs the battery monitoring control command to the monitoring unit 44 with ID=1 in S41a. The wireless communication unit 46 receives the instruction of the battery monitoring control command, and transmits the battery monitoring control command to the monitoring unit 44 with ID=1 in S42a. The monitoring unit 44 with ID=1 executes monitoring control in S43a, and returns the battery-related information to the wireless communication unit 46 in S44a. Then, the wireless communication unit 46 returns the battery-related information acquired by the monitoring unit 44 with ID=1 to the control device 50.

On the other hand, in S41b, the control device 50 instructs the wireless communication unit 46 to output the battery monitoring control command to the monitoring unit 44 with ID=2. The wireless communication unit 46 receives the instruction of the battery monitoring control command, and transmits the battery monitoring control command to the monitoring unit 44 with ID=2 in S42b. In S43b, the monitoring unit 44 with ID=2 executes monitoring control, and in S44b, returns the battery-related information to the wireless communication unit 46. Then, the wireless communication unit 46 returns the battery-related information acquired by the monitoring unit 44 with ID=2 to the control device 50.

In this way, the wireless communication unit 46 of a certain monitoring device 40 (for example, 401) can wirelessly transmit the battery-related information of IDs=1 and 2 in the cycles C11 and C12. When receiving the battery-related information in this manner, the control device 50 can receive the battery-related information from each of the monitoring units 44 at a constant cycle. The communication error rate per communication is the same as that in the case where one monitoring unit 44 is provided for each of the monitoring devices 40, but control can be easily performed.

As illustrated in FIG. 12, after the wireless communication unit 46 transmits the battery monitoring control command to the monitoring unit 44 with ID=1 in S42a, the battery-related information instructed in the previous cycle and acquired in S43z in the monitoring unit 44 may be received in S44z. In this case, the wireless communication unit 46 may return the battery-related information acquired in the previous cycle to the control device 50 in S45z.

In addition, for example, when receiving a response of the battery related information of the monitoring unit 44 with ID=1 of a certain monitoring device 40 (for example, 401) in S45a, the control device 50 may immediately transmit the battery monitoring control command in the next cycle to the monitoring unit 44 with ID=1 of the certain monitoring device 40 (for example, 401) in S41c. Then, since the wireless communication unit 46 immediately transmits the battery monitoring control command to the monitoring unit 44 with ID=1, the cycle can be shortened.

### <Modification of Sequence in FIG. 12>

In the above example, the control device 50 divides the instruction information of the battery monitoring control command and transmits the divided instruction information in 41a and 41b. However, the control device 50 may collectively instruct the monitoring units 44 with IDs=1 and 2.

### <Second Example of Transmission Data>

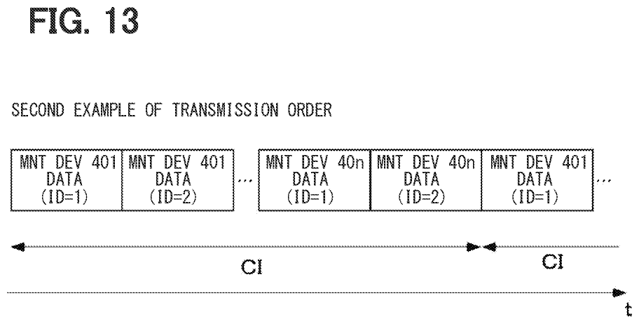

A second example of transmission data will be described below. As illustrated in FIG. 13, the wireless communication unit 46 of each of the monitoring devices 40 (401 . . . 40n) may wirelessly transmit the battery-related information acquired by each of the monitoring units 44 together.

When the control device 50 manages the schedule of wireless transmission by the monitoring devices 40, each of the monitoring devices 40 performs wireless transmission during a time allocated according to the schedule. As illustrated in FIG. 13, when data is sequentially received from the monitoring units 44 with IDs=1 and 2 connected in daisy-chain fashion, the wireless communication unit 46 may transmit these pieces of data together in a cycle CI in a time allocated to each of the monitoring devices 40.

It is desirable for the control device 50 to compare the cell characteristics and the like at one time by obtaining the characteristics of all the battery cells 22 constituting the assembled battery 12 at one time, but it may take time until the data (for example, the cell voltage, and the like) of all the monitoring units 44 are obtained. By allocating time as in the second example of the transmission data, it is possible to use data acquired at timings as close as possible in time, preferably at the same timing. Thus, the characteristics can be obtained in synchronization with the timing. The control device 50 can timely collect the battery-related information from the monitoring devices 40 (401 . . . 40n), and can accurately monitor the voltage information of the assembled battery 12. Accordingly, the control device 50 can perform process with a margin in timing.

### Summary of the Present Embodiment

According to the present embodiment, the plurality of monitoring units 44 (monitoring ICs) are mounted on each of the monitoring devices 40, and the plurality of monitoring units 44 acquires the battery-related information including at least the information indicating the state of the battery. The wireless communication unit 46 wirelessly transmits the battery-related information acquired by the plurality of monitoring units 44. Therefore, compared to a configuration in which only one monitoring unit 44 is provided for the wireless communication unit 46, the amount of data transmitted by the wireless communication unit 46 can be increased, and the number of times of wireless transmission of the battery-related information can be restricted.

When the plurality of monitoring units 44 are provided for one wireless communication unit 46, the amount of data to be wirelessly transmitted can be increased. However, since wireless communication is applied, there is a restriction on the wireless communication state. Therefore, even when the amount of data is increased, it is desirable to restrict the error rate as much as possible and restrict the number of retransmissions and the number of wireless transmissions as much as possible. By restricting the error rate and the number of retransmissions as much as possible, a decrease in the number of times of monitoring the battery per unit time can also be restricted, which leads to early detection of an abnormality related to the battery.

Therefore, the wireless communication unit 46 selects and wirelessly transmits different types of information for each of the monitoring units 44 among the battery-related information acquired by the plurality of monitoring units 44. In this case, the wireless communication unit 46 selects different types of information and wirelessly transmits the selected information collectively, thereby reducing the total amount of data to be transmitted collectively. As a result, it is possible to restrict communication errors in wireless communication, and as a result, it is possible to restrict a decrease in the number of times of battery monitoring related to the assembled battery 12.

The wireless communication unit 46 may wirelessly transmit a combination of types of data having a smaller data amount than a combination of types of data having the largest data amount among the battery-related information acquired by the plurality of monitoring units 44. The wireless communication unit 46 may wirelessly transmit the battery-related information acquired by the plurality of monitoring units 44 in such a manner that the total amount of data to be wirelessly transmitted collectively is within a predetermined range by combining the types of data of the battery-related information.

In addition, since the monitoring device 40 is disposed across the plurality of battery modules 20 and the monitoring units 44 is provided for each of the plurality of battery modules 20, the number of wireless communication units 46 can be reduced and the cost can be reduced as compared with a configuration in which the monitoring units 44 is individually provided for the wireless communication unit 46. Since the monitoring devices 40 are disposed along the side surface of the battery modules 20, for example, the height in the Z direction can be configured to be lower than that in a second embodiment described later, and the entire structure can be configured to be lower in height.

### Second Embodiment

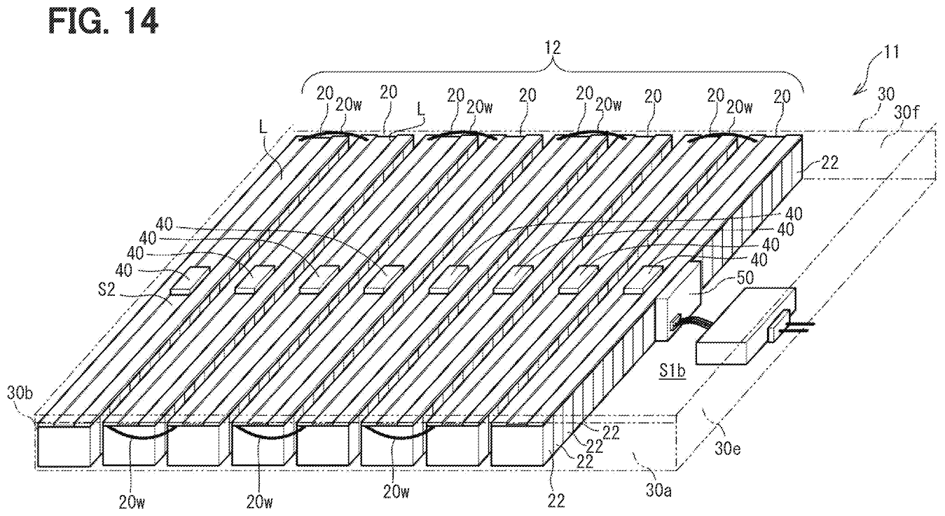

The second embodiment will be described with reference to FIG. 14. As illustrated in FIG. 14, the monitoring device 40 may be disposed on an upper surface of each of the plurality of battery modules 20. The monitoring device 40 is disposed at an intermediate portion of each of the battery modules 20 extending in the Y direction, and connects the detection lines L in both directions in the Y direction. FIG. 14 illustrates a configuration in which the monitoring device 40 is disposed at a center position in the Y direction on the upper surface of each of the battery modules 20, but the monitoring device 40 may not necessarily be disposed at the center position in the Y direction. It is not limited to the center position in the Y direction and may be arranged at any position as long as it is the intermediate portion in the Y direction.

Each of the monitoring devices 40 includes a plurality of (for example, two or more) monitoring units 44, and is configured by connecting detection lines L to the plurality of monitoring units 44, respectively. Each of the monitoring units 44 is configured by an integrated circuit device called a monitoring IC. The monitoring units 44 can detect the voltages of the plurality of battery cells 22 in each of the battery modules 20 by the detection lines L. An upper end of each of the monitoring devices 40 is protrudes more than the upper ends of the bus bar covers 27 in the Z direction.

As in the above-described embodiment, the control device 50 includes the wireless IC 54, and each of the monitoring devices 40 includes the wireless communication unit 46. The housing 30 is provided with a gap at the upper inner end in the Z direction, and the gap is provided as a propagation space S2 of radio waves. The control device 50 can wirelessly communicate with the plurality of monitoring devices 40 via the propagation space S2. If the wireless IC 54 of the control device 50 can communicate with the wireless communication units 46 of the plurality of monitoring devices 40 by a direct wave, it is possible to maintain a good propagation environment of the radio waves.

Since the monitoring devices 40 are disposed so as to protrude more than the upper ends of the bus bar covers 27, the radio waves propagate in the propagation space S2 above the upper ends of the bus bar covers 27, and thus communication between the control device 50 and the monitoring devices 40 is facilitated. According to the present embodiment, since the monitoring devices 40 do not need to be disposed on the side surfaces in the Y direction of the battery modules 20, the width in the Y direction of the housing 30 can be restricted, and the housing 30 can be downsized.

### Third Embodiment

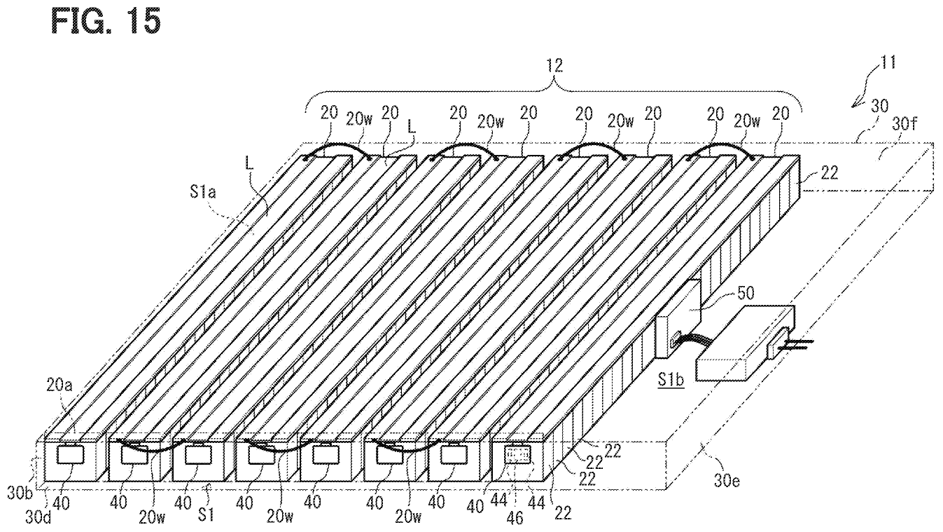

A third embodiment will be described with reference to FIG. 15. As illustrated in FIG. 15, the monitoring devices 40 are disposed along the side surfaces in the Y direction of the battery modules 20, respectively. Each of the monitoring devices 40 includes the wireless communication unit 46 and the monitoring units 44, and the monitoring units 44 are connected to the detection line L. Each of the monitoring devices 40 may include only one monitoring unit 44. The monitoring units 44 are connected to one end of the detection line L extending in the Y direction. Accordingly, the monitoring units 44 can detect the voltages of the battery cells 22. As in the first embodiment, the space S1 is provided on the inner side of the first wall surface 30a of the housing 30. The wireless IC 54 of the control device 50 can perform wireless communication with the wireless communication units 46 of the monitoring devices 40 by using the space S1 as a pseudo waveguide space. The monitoring devices 40 are arranged periodically (for example, at equal intervals) along the X direction. Even in such an arrangement mode of the third embodiment, it is possible to arrange the monitoring devices 40 while reducing the height as in the first embodiment described above.

### Fourth Embodiment

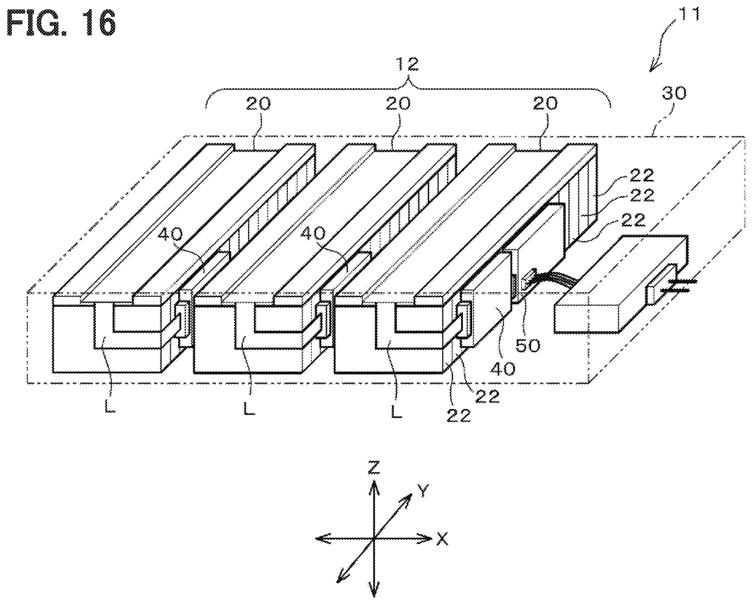

A fourth embodiment will be described with reference to FIG. 16. As illustrated in FIG. 16, the monitoring devices 40 may be disposed along the side surfaces in the X direction of the battery modules 20, respectively. The detection line L is disposed along the upper surface of each of the battery modules 20, extends to the side surface in the X direction through the side surface in the Y direction of each of the battery modules 20 in an L shape, and is further connected to the monitoring device 40 on the side surface in the X direction along the Y direction.

As in the above-described embodiments, the control device 50 is wirelessly connected to the monitoring devices 40. Even in such an arrangement mode of the fourth embodiment, it is possible to arrange the monitoring devices 40 while reducing the height as in the first embodiment described above. According to the present embodiment, since the monitoring devices 40 do not need to be disposed on the side surfaces in the Y direction of the battery modules 20, the width in the Y direction of the housing 30 can be restricted, and the housing 30 can be downsized. In addition, since the monitoring devices 40 do not need to be disposed on the upper surfaces of the battery modules 20, the height of the housing 30 in the Z direction can be restricted, and the housing 30 can be downsized. When the communication connection environment between the control device 50 and the monitoring devices 40 is regarded as important, the space S1 or S2 described in the above embodiments may be provided at the end in the Y direction or the upper end in the Z direction of the housing 30.

### Fifth Embodiment

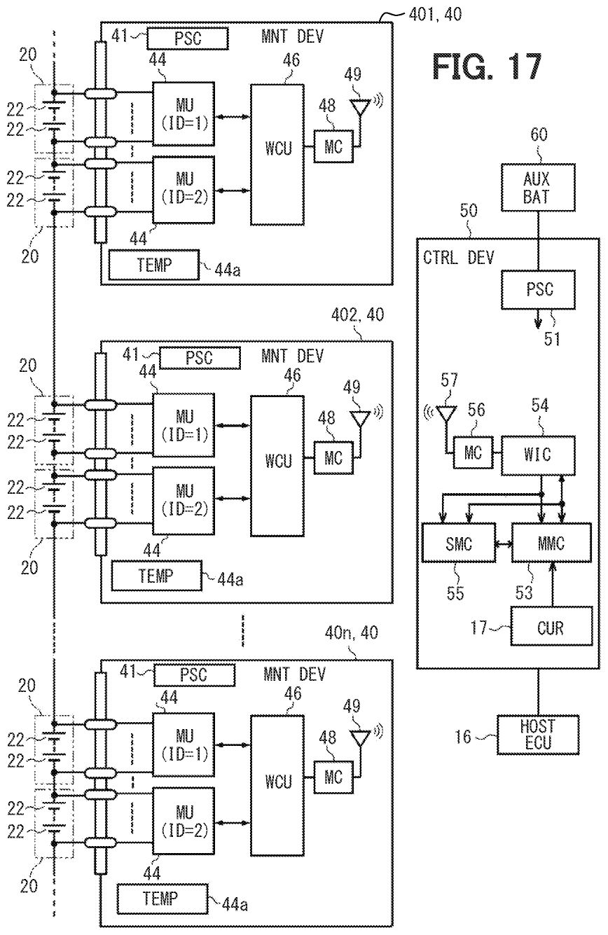

A fifth embodiment will be described with reference to FIG. 17. In the first embodiment, the wireless communication unit 46 and the monitoring units 44 are connected in daisy-chain fashion, but the present disclosure is not limited thereto. As illustrated in FIG. 17, the wireless communication unit 46 and the monitoring units 44 may be connected in a network topology by a wired connection of a star connection.

The monitoring units 44 are connected by wire on the same substrate as the wireless communication unit 46. Therefore, in the daisy-chain connection, when an abnormality occurs in some of the monitoring units 44, there is a possibility that the wireless communication unit 46 cannot maintain communication with the other monitoring units 44.

In the configuration of the network topology of the present embodiment, even when a failure occurs in some of the plurality of monitoring units 44, the communication connection can be maintained separately from the other monitoring units 44, so that the communication can be normally continued between the other monitoring units 44 and the wireless communication unit 46. In addition, in the present embodiment, the same operation and effects as those of the daisy-chain connection mode are obtained.

At least two or more of a star network, a mesh network, and a daisy-chain network may be mixed to configure the network.

### Other Embodiments

The present disclosure is not limited to the embodiment described above, and, for example, may be modified or expanded, which will be described. Any one of the monitoring devices 40 (401 . . . 40n) may be configured to serve as a relay. For example, the monitoring device 40 disposed at a position closest to the control device 50 (for example, the monitoring device 401) may serve as a relay. For example, when the monitoring device 401 serves as a relay, the wireless IC 54 of the control device 50 communicates with the wireless communication unit 46 of the monitoring device 401, and the wireless communication unit 46 of the monitoring device 401 communicates with the wireless communication unit 46 of the monitoring device 402.

For example, in the above-described embodiments, an example has been described in which the wireless communication unit 46 includes the microcontroller and the wireless IC, and each of the monitoring units 44 includes the ASIC. However, the present disclosure is not limited thereto. The wireless communication unit 46 may have a hardware configuration in which functions are divided into a wireless transmission unit and a wireless reception unit. A configuration in which each of the monitoring devices 40 does not include a microcontroller may be applied. That is, the wireless communication unit 46 may include only the wireless IC, and may be configured to establish communication connection with the monitoring units 44. The sensing control by the monitoring unit 44 and the schedule control of the self-diagnosis (for example, self-diagnoses A, B and C) may be executed by the main microcontroller 53 of the control device 50.

In the above-described embodiments, an example has been described in which the main microcontroller 53 of the control device 50 estimates the internal resistance and the open circuit voltage of the battery cell 22 based on the cell voltage and the cell current, and calculates the SOH based on the estimated internal resistance and the estimated open circuit voltage. However, the estimation of the internal resistance, the estimation of the open circuit voltage, and the calculation of the SOH are not limited to this example. For example, some or all of the processes among the estimation of the internal resistance, the estimation of the open circuit voltage, and the calculation of the SOH may be performed inside each of the monitoring devices 40, for example, by the wireless communication unit 46.

While an example in which each of the monitoring devices 40 acquires battery monitoring information on the basis of the acquisition request from the controller 50 has been described, the present disclosure is not limited to this example. Each of the monitoring devices 40 may autonomously acquire battery monitoring information and may transmit the battery monitoring information to the control device 50 on the basis of a transmission request from the control device 50.

In the present embodiment, an example in which the monitoring devices 40 are connected to the control devices 50 in a star wireless network has been described. However, the network topology of the control device 50 and the monitoring devices 40 is not limited to this example. A wired connection network may be mixed. As described above, the network topology between the control device 50 and the monitoring devices 40 is not particularly limited.

In the present embodiment, when starting the vehicle 10, a user operates the ignition switch from OFF to ON, and at this time, a start signal is given to the control device 50. In this way, an example in which the control device 50 is activated by switching the ignition switch from OFF to ON has been described. That is, when the ignition switch is in the OFF state, the control device 50 is in a sleep state.

However, the operation of the control device 50 when the ignition switch is in the OFF state is not limited to this example. For example, even when the ignition switch is turned off, the control device 50 may be activated. In this case, the control device 50 may maintain the connection establishment with the monitoring devices 40.

The arrangement and the number of the battery modules 20 and the battery cells 22 constituting the assembled battery 12 are not limited to the above-described example. The arrangement mode of the monitoring devices 40 and/or the control device 50 in the battery pack 11 is not limited to the above-described form.

Although an example in which one control device 50 is provided in the battery pack 11 has been described, the present disclosure is not limited thereto, and a plurality of control devices 50 may be provided. That is, the battery pack 11 may include a plurality of monitoring devices 40 and one or more control devices 50. In the battery pack 11, a plurality of sets of wireless communication systems constructed between the control device 50 and the plurality of monitoring devices 40 may be provided.

Although the embodiments in which each of the monitoring devices 40 includes the plurality of monitoring units 44 have been described, the present disclosure is not limited thereto, and each of the monitoring devices 40 may include one monitoring unit 44 (monitoring IC). In this case, the wireless communication unit 46 may be provided for each monitoring unit 44. The wireless communication unit 46 may be configured not to include the microcontroller. In this case, the main microcontroller 53 may constitute a part of the functions of the wireless communication unit 46 described above.

Although examples in which one monitoring device 40 is disposed for each of one or two battery modules 20 have been described, the present disclosure is not limited thereto. For example, one monitoring device 40 may be disposed for three or more battery modules 20. For example, two or more monitoring devices 40 may be disposed for one battery module 20.

In the above-described embodiments, one battery module 20 is set as one group, and a plurality of groups are arranged in parallel and stored in the battery pack 11. However, the present disclosure is not limited thereto. One group may not be provided in units of one battery module 20, one battery stack, and one battery block. The battery cells 22 obtained by dividing one battery module 20 may be regarded as one group. In addition, for example, in the form of a cell to pack or a cell to chassis, the battery cells 22 may be packaged and stored in the vehicle 10 in a module-less manner. In such a case, one or more battery cells 22 may be regarded as a group.

The monitoring device 40 may be configured across a plurality of groups of the battery cells 22. In this case, a plurality of monitoring units 44 may be provided for each group. The monitoring device 40 may be provided for each group, and in this case, the monitoring units 44 may be configured to monitor the battery cells 22 for each group. The number of battery cells 22 included in each group may not be the same, and may be different for each group.

The control device 50, the monitoring devices 40, the host ECU 16 and the technique according to the present disclosure may be achieved by a dedicated computer provided by constituting a processor and a memory programmed to execute one or more functions embodied by a computer program. Alternatively, the control device 50, the monitoring devices 40, the host ECU 16 and the technique according to the present disclosure may be achieved by a dedicated computer provided by constituting a processor with one or more dedicated hardware logic circuits.

Alternatively, the control device 50, the monitoring devices 40, the host ECU 16 and the technique according to the present disclosure may be achieved using one or more dedicated computers constituted by a combination of the processor and the memory programmed to execute one or more functions and the processor with one or more hardware logic circuits. The computer program may be stored, as instructions to be executed by a computer, in a tangible non-transitory computer-readable medium.

Namely, the means and/or the functions which are provided by the processor and the like may be provided by software stored in tangible memory devices and computers for executing them, only software, only hardware, or a combination thereof. For example, some or all of the functions provided by the authentication processor may be realized as hardware. A mode in which a certain function is realized as hardware includes a mode in which one or more ICs are used.

The processor may be implemented using a CPU, an MPU, a GPU, or a DFP. DFP is an abbreviation for Data Flow Processor. The processor may be realized by combining multiple types of arithmetic process units such as a CPU, an MPU, and a GPU. The processor may be realized as a system on chip (SoC). SoC is an abbreviation for System on Chip.

Furthermore, a portion that executes various processes described in the above-described embodiments may be realized by using hardware such as an FPGA or an ASIC. The various programs may be stored in a non-transitional substantive recording medium. As the storage medium of the program, a non-transitory computer readable medium such as an HDD, an SSD, a flash memory, and an SD card can be adopted. FPGA is an abbreviation for Field Programmable Gate Array. HDD is an abbreviation for Hard Disk Drive. SSD is an abbreviation for Solid State Drive. SD is an abbreviation for Secure Digital.

Although the present disclosure has been described in accordance with the embodiments, it is understood that the present disclosure is not limited to such embodiments or structures. The present disclosure encompasses various modifications and variations within the scope of equivalents. In addition, various combinations and modes, and other combinations and modes including only one element, more elements, or less elements are also within the scope and idea of the present disclosure.

What is claimed is:

1. A battery monitoring device comprising:
a plurality of monitoring units configured to acquire battery-related information including at least information indicating a state of a battery; and
a wireless transmission unit configured to wirelessly transmit the battery-related information acquired by the plurality of monitoring units to a control device.

2. The battery monitoring device according to claim 1, wherein
the wireless transmission unit is configured to collectively transmit a plurality of pieces of information in the battery-related information acquired by the plurality of monitoring units, and
the plurality of pieces of information is different types of information from each other.

3. The battery monitoring device according to claim 1, wherein
the wireless transmission unit is configured to collectively transmit a plurality of pieces of information in the battery-related information acquired by the plurality of monitoring units in a combination of types of information having a smaller data amount than a combination of types of information having a largest data in the battery-related information acquired by the plurality of monitoring units.

4. The battery monitoring device according to claim 1, wherein
the wireless transmission unit is configured to collectively transmit a plurality of pieces of information in the battery-related information acquired by the plurality of monitoring units in such a manner that a total amount of data to be transmitted collectively falls within a predetermined range by combining types of information in the battery-related information.

5. The battery monitoring device according to claim 1, wherein
the wireless transmission unit is configured to collectively transmit a plurality of pieces of information in the battery-related information acquired by the plurality of monitoring units, and
the wireless transmission unit is configured to transmit the plurality of pieces of information according to a reading time of the battery-related information acquired by the plurality of monitoring units.

6. The battery monitoring device according to claim 1, wherein
the plurality of monitoring units and the wireless transmission unit are included in a main body of the battery monitoring device,
the battery-related information includes, as types of the battery-related information, voltage information of the battery, temperature information of the battery or the main body of the battery monitoring device, and diagnosis information diagnosed in relation to the battery or the main body of the battery monitoring device, and
the wireless transmission unit is configured to wirelessly transmit the voltage information or the temperature information in combination with the diagnosis information.

7. The battery monitoring device according to claim 1, wherein
the wireless transmission unit is configured to wirelessly transmit the battery-related information at a different timing for each of the plurality of monitoring units.

8. The battery monitoring device according to claim 1, wherein
the plurality of monitoring units and the wireless transmission unit are disposed on an identical substrate.

9. The battery monitoring device according to claim 1, wherein
the wireless transmission unit and the plurality of monitoring units are communicatively connected in a network topology of a star connection.

10. The battery monitoring device according to claim 1, wherein
the plurality of monitoring units and the wireless transmission unit are included in a main body of the battery monitoring device,
the battery includes a plurality of groups, and each of the plurality of groups includes a plurality of battery cells arranged in parallel,
the main body of the battery monitoring device is configured to be disposed across a plurality of side surfaces of the plurality of groups, and
the plurality of monitoring units is provided for each of the plurality of groups, and is configured to monitor the plurality of battery cells in each of the plurality of groups.

11. The battery monitoring device according to claim 1, wherein
the plurality of monitoring units and the wireless transmission unit are included in a main body of the battery monitoring device,
the battery includes a plurality of groups, and each of the plurality of groups includes a plurality of battery cells arranged in parallel, and
the main body of the battery monitoring device is configured to be disposed on a side surface of each of the plurality of groups.

12. The battery monitoring device according to claim 1, wherein
the plurality of monitoring units and the wireless transmission unit are included in a main body of the battery monitoring device,
the battery includes a plurality of groups, and each of the plurality of groups includes a plurality of battery cells arranged in parallel,
the main body of the battery monitoring device is configured to be provided for one or more of the plurality of groups and is configured to be disposed in a space that is partially surrounded by a reflecting member and constitutes a pseudo waveguide through which an electromagnetic wave wirelessly propagates along a predetermined direction, and
the reflecting member is configured to reflect the electromagnetic wave.

13. The battery monitoring device according to claim 12, wherein
the plurality of groups is arranged in parallel in the predetermined direction, and
the main body of the battery monitoring device is configured to be disposed across two side surfaces of two adjacent groups in the plurality of groups in the space on an inner side of a wall surface of a housing extending in the predetermined direction.

14. The battery monitoring device according to claim 12, wherein
the plurality of groups is arranged in parallel in the predetermined direction, and
the main body of the battery monitoring device is configured to be disposed along a side surface in the predetermined direction of each of the plurality of groups.

15. The battery monitoring device according to claim 1, wherein
the plurality of monitoring units and the wireless transmission unit are included in a main body of the battery monitoring device,
the battery includes a plurality of groups arranged in parallel in a predetermined direction,
each of the plurality of groups includes a plurality of battery cells arranged in parallel in an intersecting direction that intersects the predetermined direction, and
the main body of the battery monitoring device is configured to be disposed at an intermediate portion in the intersecting direction on a plurality of upper surfaces of the plurality of battery cells in each of the plurality of groups.

16. A wireless transmission method comprising:
acquiring battery-related information including at least information indicating a state of a battery by a plurality of monitoring units;
transmitting the battery-related information from the plurality of monitoring units to a wireless transmission unit that is connected to the plurality of monitoring units in a wired manner; and
wirelessly transmitting the battery-related information from the wireless transmission unit to a control device.

17. A non-transitory computer readable medium storing a program including instructions for a battery monitoring device that includes a plurality of monitoring units configured to acquire battery-related information including at least information indicating a state of a battery and a wireless transmission unit communicably connected to the plurality of monitoring units and configured to wirelessly transmit the battery-related information, the instructions configured to:
cause the plurality of monitoring units to acquire the battery-related information;
cause the plurality of monitoring units to transmit the battery-related information to the wireless transmission unit; and
cause the wireless transmission unit to wirelessly transmit the battery-related information to a control device.
